(19) United States
(12) Patent Application Publication
(10) Pub. No.: US 2024/0061408 A1
(43) Pub. Date: Feb. 22, 2024

(54) QUALITY IMPROVEMENT ASSISTANCE DEVICE

(71) Applicant: OMRON Corporation, Kyoto-shi, KYOTO (JP)

(72) Inventors: Hiroyuki MORI, Kyoto-shi, KYOTO (JP); Keita SAJI, Kyoto-shi, KYOTO (JP); Mayuko TANAKA, Kyoto-shi, KYOTO (JP)

(21) Appl. No.: 18/259,547

(22) PCT Filed: Mar. 11, 2021
(86) PCT No.: PCT/JP2021/009838

§ 371 Date: Jun. 27, 2023

(30) Foreign Application Priority Data
Jan. 29, 2021 (JP) 2021-013149

(51) Int. Cl. G05B 19/418

(52) U.S. Cl. CPC G05B 19/41875; G05B 19/41865; G05B 2219/32368

(57) ABSTRACT

A quality improvement support apparatus that supports improvement in quality of products produced by a production facility includes a display unit that displays production condition information in which quality information regarding the quality occurring or detected in a production step performed by the production facility is arranged in time series in association with a production member or a component included in the production facility, wherein, in the production condition information, the quality information of each product or a plurality of the products occurring or detected in relation to the production member or the component included in the production facility is arranged in an order in which the products are produced.

### TECHNICAL FIELD

The present invention relates to a quality improvement support apparatus that supports improvement in quality of a product such as a circuit board.

### RELATED ART

As a conventional management support apparatus that analyzes causes of faults or errors in a production facility for producing printed circuit boards or the like and determines measures, apparatuses that display faults and errors in various manners have been proposed. For example, there is an apparatus that displays only inspection results or mount errors.

On the other hand, an apparatus described in Patent Document 1 is proposed as a management support apparatus that takes the passage of time into consideration. Here, a time axis of each step is displayed vertically, and a plurality of sequential steps are arranged from left to right in such a manner that the time axes of the respective steps are parallel to each other. On the time axis of each step, marks each extending in the time axis direction with a length corresponding to a period from a production start time to a production end time of a single product in the step are displayed. Production start times of the sequential steps are connected to each other by a line segment, production end times of the sequential steps are connected to each other by a line segment, and pins representing errors that occurred in the steps are arranged on the corresponding time axes.

However, with these management support apparatuses, when a plurality of types of faults or errors occurred, it was not possible to know whether those faults or errors occurred at the same time or on the same circuit board. Also, it was not possible to know which type of fault or error is successively occurring, whether such faults or errors are concentrated in a specific time or circuit board, or the faults or errors are occurring sporadically. Also, it was not possible to know state transitions, for example, which type of fault or error occurred suddenly, and which type of fault or error ended already.

### RELATED ART DOCUMENTS

### Patent Documents

Patent Document 1: JP 628701862

### SUMMARY OF THE INVENTION

### Problem to be Solved by the Invention

The present invention was made in view of the problems described above, and has an object of providing technology that makes it possible to analyze causes of faults and errors and determine measures in a short time when a plurality of types of faults and errors occurred in a production facility.

### Means for Solving the Problems

An aspect of the present invention for solving the above-described problems is a quality improvement support apparatus that supports improvement in quality of products produced by a production facility, the quality improvement support apparatus including:

a display unit that displays production condition information in which quality information regarding the quality occurring or detected in a production step performed by the production facility is arranged in time series in association with a production member or a component included in the production facility, wherein, in the production condition information, the quality information of each unit product constituted by one or a plurality of the products is arranged in an order in which the products are produced.

In the production condition information according to the present invention, the quality information of each unit product constituted by one or a plurality of products is associated with the production member or the component and is arranged in the order in which the products are produced. Accordingly, it is possible to recognize chronological fluctuations in the quality information with respect to successively produced unit products each constituted by one or a plurality of products. Even when a plurality of types of errors occurred, it is possible to narrow down causes of those abnormalities based on chronological fluctuations in the quality information of successively produced unit products, which is associated with the production member or the component. It is also possible to find a temporal tendency of the occurrence of abnormalities, such as sudden occurrence or continuous occurrence. Accordingly, even when a plurality of types of faults and errors occurred, it is possible to separate causes that affect such a temporal tendency of the occurrence of abnormalities, and it is possible to analyze causes and determine measures in a short time.

In the present invention, with respect to a plurality of the production members or the components relating to the unit product, the quality information of the same unit product may be arranged at the same position in the time series.

In this case, it is possible to not only recognize chronological fluctuations in the quality information of successively produced unit products with respect to each production member or each component, but also recognize fluctuations in the quality information occurring in the same unit product in production steps, because the quality information of the same unit product is arranged at the same position in the time series with respect to the plurality of related production members or components. Even when a plurality of types of errors occurred, it is possible to find that an abnormality occurring or detected in an apparatus was caused by an abnormality occurring or detected in another apparatus that is upstream of the apparatus in the production line, and thus it is possible to narrow down causes of abnormalities to some apparatuses. Therefore, when a plurality of types of faults and errors occurred, it is possible to analyze causes and determine measures in a short time.

Here, in the case where the quality information associated with the plurality of production members or components is displayed, the plurality of production members or components may be arranged in the order in which unit products are processed in the production steps, or the production members or the components may be arranged collectively based on their functions.

In the present invention, the quality information may include a plurality of types of quality information, and
the respective types of quality information may be displayed in different display manners.

In this case, it is possible to clearly recognize temporal fluctuations in each type of quality information. Accordingly, when a plurality of types of faults and errors occurred, it is possible to more efficiently analyze causes and determine measures. In the present invention, event information indicating an event occurring or

executed in relation to the production member or the component may be arranged in time series together with the quality information in accordance with a temporal order between a timing of the occurrence or execution of the event and the quality information occurring or detected in relation to the production member or the component.

In this case, an event that may cause a fault, an error, or the like or that may have an effect of reducing faults, errors, or the like is displayed together with the quality information. Therefore, when a plurality of faults and errors occurred, it is possible to more efficiently analyze causes and determine measures.

In the present invention, marks each representing one or a plurality of the products may be arranged in the order in a time axis direction defined for each production member or component relating to the quality information, and the quality information may be displayed in association with the marks.

This configuration facilitates visual recognition of the relationship between the production member or the component, the one or plurality of products, and the order in which the products are produced. Accordingly, it is possible to separate causes that affect a temporal tendency of the occurrence of abnormalities, such as sudden occurrence or continuous occurrence, and it is possible to more efficiently analyze causes and determine measures when a plurality of types of faults and errors occurred.

In the present invention, the production condition information may include chronological quality information regarding the quality occurring or detected in relation to the production member or the component, the chronological quality information being arranged in time series showing passage of time in a predetermined period.

In this case, it is possible to recognize fluctuations in the quality information based on temporal expression that is different from temporal expression in accordance with the production order of unit products. Accordingly, when a plurality of types of faults and errors occurred, it is possible to more efficiently analyze causes and determine measures. Such chronological quality information may be displayed on a screen in the display unit other than the screen displaying the above-described production condition information in which the quality information of each unit product is arranged in the production order, or the chronological quality information and the production condition information may be displayed on the same screen. In the case where these types of information are displayed on the same screen, it is possible to more efficiently analyze causes and determine measures when the time ranges of these types of information are matched.

In the present invention, a plurality of pieces of the chronological quality information corresponding to a plurality of the production members or the components may be arranged vertically, the chronological quality information showing the passage of time in the predetermined period along a horizontal axis.

In this case, it is possible to recognize fluctuations in the quality information simultaneously occurring in the production steps, and to narrow down causes of abnormalities to causes of fluctuations simultaneously occurring in the production members or the components. Therefore, when a plurality of types of faults and errors occurred, it is possible to more efficiently analyze causes and determine measures.

### Effects of the Invention

According to the present invention, it is possible to analyze causes of faults and errors and determine measures in a short time when a plurality of types of faults and errors occurred in a production facility.

### BRIEF DESCRIPTION OF THE DRAWINGS

FIG. 1 is a diagram showing a schematic configuration of a production facility according to an embodiment of the present invention.

FIG. 2 is a functional block diagram of a management apparatus according to an embodiment of the present invention.

FIG. 3 is a functional block diagram of a manager terminal according to an embodiment of the present invention.

FIG. 4 is a functional block diagram of an operator terminal, a mounting/inspection apparatus, and a program management server according to an embodiment of the present invention.

FIG. 5 is a schematic diagram showing a configuration of a mounter according to an embodiment of the present invention.

FIG. 6 is a diagram showing an example of production log data according to an embodiment of the present invention.

FIG. 7 is a functional block diagram of the management apparatus clarifying a relationship with a mounter according to an embodiment of the present invention.

FIG. 8 is a diagram showing an example of a production condition map display screen in a manager terminal according to Embodiment 1 of the present invention.

FIGS. 9A and 9B are diagrams showing an example of items displayed in a production condition map according to Embodiment 1 of the present invention.

FIG. 10 is a diagram showing an example of a production condition map display screen according to Embodiment 2 of the present invention.

FIG. 11 is a diagram showing an example of a production condition map display screen according to Embodiment 3 of the present invention.

FIG. 12 is a diagram showing an example of a production condition map display screen according to Embodiment 4 of the present invention.

FIG. 13 is a diagram showing an example of a production condition map display screen according to Embodiment 5 of the present invention.

FIG. 14 is a diagram showing an example of a production condition map display screen according to Embodiment 6 of the present invention.

FIG. 15 is a diagram showing an example of a production condition map display screen according to Embodiment 7 of the present invention.

FIG. 16 is a diagram showing an example of a production condition map display screen according to Embodiment 8 of the present invention.

FIG. 17 is a functional block diagram of the management apparatus according to an application example of the present invention.

FIG. 18 is a schematic diagram for describing characteristics of the present invention.

### EMBODIMENTS OF THE INVENTION

### Application Example

The following describes an application example of the present invention with reference to the drawings.

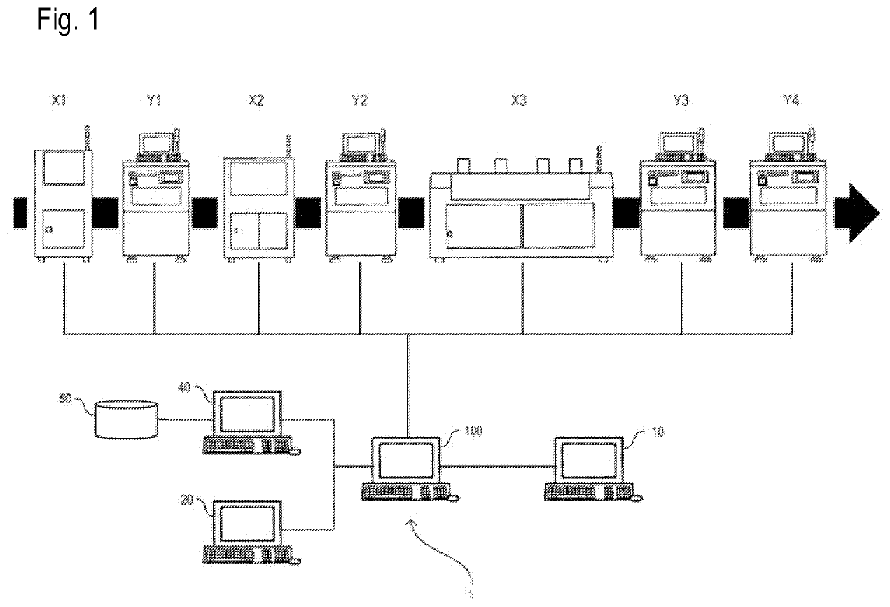

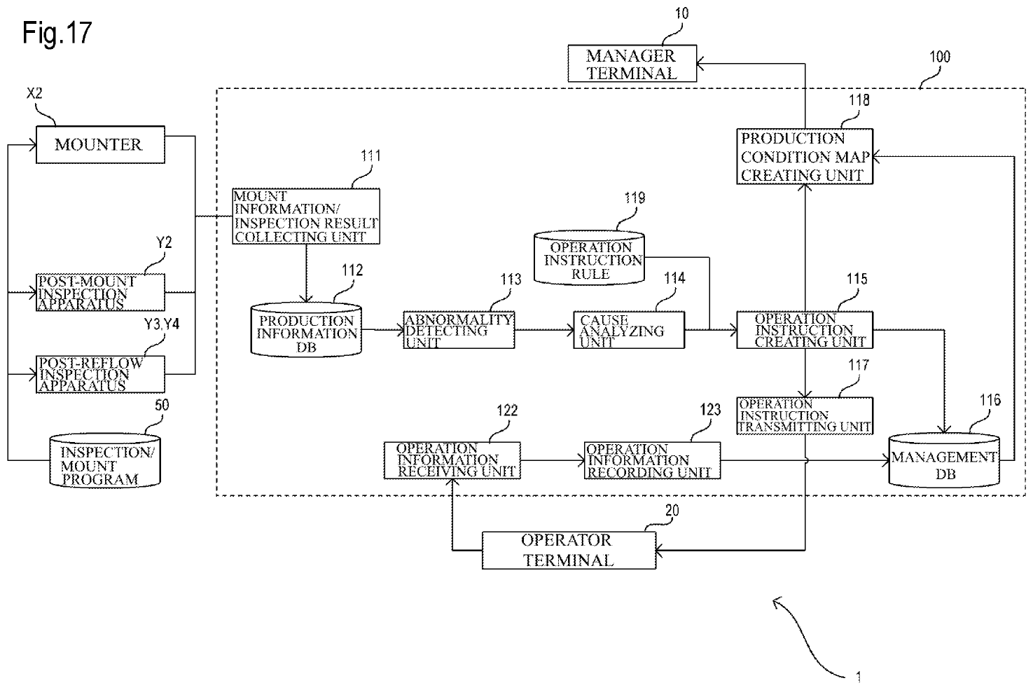

FIG. 17 shows a management system 1 to which the present invention is applied. The management system 1 includes a management apparatus 100 and a manager terminal 10 and an operator terminal 20 that are communicably connected to the management apparatus 100 via a network. A production facility included in a surface mount production line for printed circuit boards includes a mounter X2, a post-mount inspection apparatus Y2, and post-reflow inspection apparatuses Y3 and Y4 that are communicably connected to the management apparatus 100 via a network. The production facility includes a printing apparatus X1, a reflow furnace X3, and a post-printing inspection apparatus Y1 as shown in FIG. 1. The management apparatus 100 according to the present invention can be operated by being connected to these apparatuses as well via a network as descried later, but the following describes the management apparatus 100 in the configuration shown in FIG. 17. The manager terminal 10 corresponds to a quality improvement support apparatus according to the present invention. A configuration is also possible in which the manager terminal 10 constitutes the quality improvement support apparatus according to the present invention including some or all units of the management apparatus 100.

A mount information/inspection result collecting unit 111 of the management apparatus 100 collects mount information from the mounter X2 and inspection results from the post-mount inspection apparatus Y2 and the post-reflow inspection apparatuses Y3 and Y4, and records the collected information and inspection results in a production information database (DB) 112.

Based on information recorded in the production information database 112, an abnormality detecting unit 113 totals each type of faults and errors occurring in or detected by mounting apparatuses or the inspection apparatuses, performs abnormality determination, and detects an abnormality in any component on a printed circuit board. A cause analyzing unit 114 analyzes causes of the abnormality detected by the abnormality detecting unit 113. The results of totaling, abnormality determination, and abnormality analysis are recorded in a management database 116.

An operation instruction creating unit 115 creates an operation instruction for solving the abnormality based on an operation instruction rule 119 in accordance with the causes of the abnormality found through analysis by the cause analyzing unit 114. Non-limited examples of operation instructions relating to the mounter X2 include maintenance and replacement of a nozzle.

The operation instruction created by the operation instruction creating unit 115 is recorded in the management database 116 together with the site and conditions of the abnormality. Also, the operation instruction created by the operation instruction creating unit 115 is transmitted to the operator terminal 20 via an operation instruction transmitting unit 117.

Operation information regarding the status of response to the transmitted operation instruction information is input to the operator terminal 20. The operation corresponding to the instruction transmitted to the operator terminal 20 is not always performed and may not be performed. Therefore, when the instructed operation has been performed, information indicating that the operation has been performed is input to the operator terminal 20. In the case where information indicating that the operation has been performed is not input to the operator terminal 20, the operation has not been performed. That is, execution status information indicating whether or not the instructed operation has been performed is transmitted as the operation information from the operator terminal 20 to an operation information receiving unit 120 of the management apparatus 100.

The operation information received by the operation information receiving unit 120 is recorded in the management database 116 in association with the site of the abnormality corresponding to the operation content by an operation information recording unit 121.

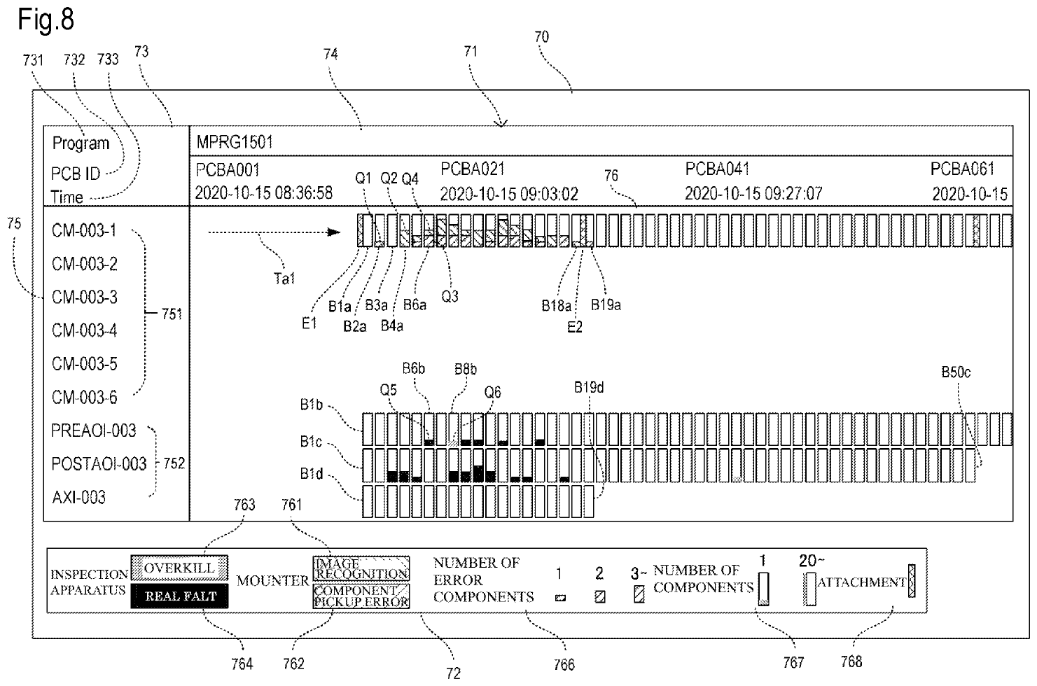

A production condition map creating unit 118 creates a production condition map based on information recorded in the management database 116. Specifically, the production condition map is data that constitutes a production condition map display screen 70 (see FIG. 8) displayed in a production condition map display unit 12 of the manager terminal 10.

The production condition map shows aggregate results of respective types of faults and errors occurring in or detected by the mounting apparatuses or the inspection apparatuses and operation information in time series. The production condition map may show both or either one of the aggregate results of respective types of faults and errors occurring in or detected by the mounting apparatuses or the inspection apparatuses and the operation information.

The production condition map display screen 70 includes a main part 71 and a legend part 72. The names of items “Program” 731, “PCB ID” 732, and “Time” 733 are displayed in an upper left field 73 of the main part 71, and information corresponding to these items is displayed in an upper right field 74.

The names of mounting apparatuses and inspection apparatuses included in a single line are displayed in a header column 75 in a lower left field of the production condition map display screen. Here, “CM-003-1” to “CM-003-6”, which are mounters, “PREAOI-003”, which is a post-mount inspection apparatus, and “POSTAOI-003” and “AXI-003”, which are post-reflow inspection apparatuses, are displayed in the header column 75.

A plurality of vertically elongated rectangular marks are displayed in a lower right field 76 of the main part 71 of the production condition map display screen 70. Here, each mark represents a circuit board (hereinafter, marks representing circuit boards will also be referred to as “circuit boards”). Circuit boards that are arranged in the lower right field 76 in the same row as an apparatus displayed in the header column 75 indicate that the circuit boards represented by those marks are mounting targets of that apparatus. A plurality of circuit boards arranged in the same row are arranged in the order in which the circuit boards are subjected to mounting. When focusing on a specific apparatus displayed in the header column 75, for example, the mounter CM-003-1, a time axis Ta1 (not displayed) defined for the mounter CM-003-1 extends in such a manner that time progresses rightward, and a plurality of circuit boards B1a, B2a, B3a, . . . are arranged along the time axis Ta1. Also, timings of events, which are any of 4M changes that occurred in the apparatus, are displayed in time series in the row direction as event information E1 and the like, which are represented by rectangles thinner than the circuit boards, together with the circuit boards processed by the apparatus. Out of the plurality of circuit boards and the like displayed in the lower right field 76 of the main part 71 of the production condition map display screen 70, circuit boards arranged in the same column represent the same circuit board.

The numbers of faults and errors occurring in or detected for a circuit board in a step performed using the apparatus displayed in the header column 75 in the same row as the circuit board are displayed as a cumulative bar graph that shows the numbers of respective types of errors and faults and overlaps with the circuit board displayed in the lower right field 76 of the main part 71 of the production condition map display screen 70.

A legend showing correspondence between types of errors, faults, etc., displayed in such a manner as to overlap with circuit boards and display manners thereof is provided in the legend part 72 below the main part 71 of the production condition map display screen 70.

In FIG. 8, the event information E1 arranged on the left side of the circuit board B1a in the first row of the lower right field 76 corresponding to the mounter CM-003-1 represents replacement of a feeder. For example, a case is conceivable where a feeder provided with a new reel was prepared because components were going to run short, then all components were used up from a reel on a feeder attached to the mounter, and the feeder was replaced with the prepared feeder.

Cumulative bar graphs displayed in such a manner as to overlap with the circuit board B1a and the like arranged on the right side of the event information E1 in the first row of the lower right field 76 in the production condition map display screen 70 indicate frequent occurrence of component pickup errors. Also, cumulative bar graphs displayed in such a manner as to overlap with circuit boards B1b, B1c, etc., arranged in the same rows as the post-mount inspection apparatus PREAOI-003 and the post-reflow inspection apparatus POSTAOI-003 indicate frequent occurrence of real faults.

Event information E2 indicates that, under the above circumstances, an operation instruction to check the attached state of the reel on the newly-attached feeder was issued, and the reel on the feeder attached to the mounter CM-003-1 was once removed and again attached based on the operation instruction. It can be found that, as a result, the conditions were improved, and component pickup errors and real faults did not occur after the reel was reattached.

As described above, in the production condition map display screen 70, the circuit board B1a and the like, which are mounting targets, are arranged in the time axis direction with respect to each apparatus constituting the printed circuit board mount production line, the time series of respective apparatuses are aligned, and aggregate results of respective types of errors are displayed in time series by being overlaid on the circuit board B1a and the like arranged in this manner. Therefore, it is possible to narrow down causes of an abnormality based on simultaneously occurring faults and errors. Also, it is possible to find time dependency such as whether or not faults and errors occurred simultaneously, successively, in a concentrated manner, or sporadically. Therefore, it is possible to determine whether it is necessary to take measures at the present time or there is no longer a need to take measures. Also, event information is arranged and displayed along the time series where the circuit board B1a and the like are arranged, and therefore, it is possible to find causes of errors and measures that were effective to improve the conditions, for example. As described above, when a plurality of types of faults and errors occurred or are detected, it is possible to analyze causes and determine measures in a short time with use of the production condition map display screen 70.

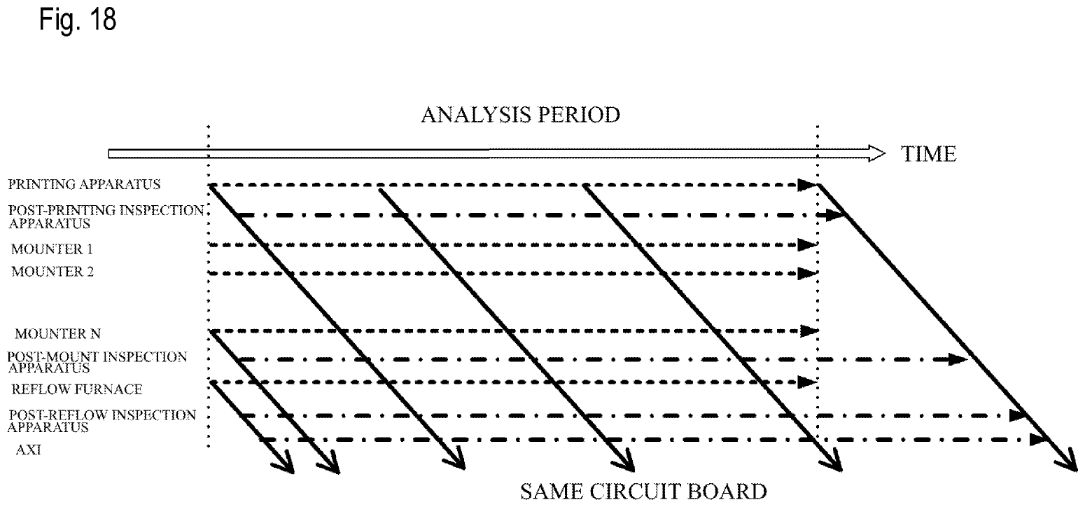

FIG. 18 is a schematic diagram for describing characteristics of the present invention applied to the manager terminal 10 including the production condition map display unit 12 that displays the production condition map display screen 70 described above.

This diagram shows a relationship between a range displayed in the production condition map display screen 70 or the like and an analysis period that is a time range of mount information and inspection results that are analyzed by the cause analyzing unit 114 of the management apparatus 100 to analyze causes of an abnormality.

In FIG. 18, the mounting apparatuses and the inspection apparatuses are arranged from the top to the bottom in the order of mount steps performed in the printed circuit board mount production line. When an analysis period shown by broken lines is assumed, mount time points in the printing apparatus X1, the mounters 1 to N (X2), and the reflow furnace X3 progress as shown by broken line arrows. Also, time points (inspection time points) at which printed circuit boards, which are inspection targets, are mounted on the post-printing inspection apparatus Y1, the post-mount inspection apparatus Y2, and the post-reflow inspection apparatuses Y3 and Y4 progress as shown by dash dotted line arrows. Each solid line arrow shows mount time points and inspection time points of the same circuit board.

When a time range between two dotted lines is set as an analysis period for analyzing an abnormality, it can be found that there are circuit boards for which the steps from printing to post-reflow inspection are within the analysis period and circuit boards for which only some of the steps are within the analysis period. That is, when a certain time range is set as the analysis period, inspection results cannot be assigned to all circuit boards and components mounted by the mounting apparatuses due to lack of some mount information or inspection results. Therefore, in the present invention, analysis periods are displayed on a circuit-board-by-circuit-board basis as shown in FIG. 8, and accordingly, it is possible to align analysis periods with respect to the same circuit board. Therefore, when a plurality of types of faults and errors occurred or are detected, it is possible to analyze causes and determine measures in a short time compared with a case where analysis periods are aligned based on time points in the respective mounting apparatuses (display by time). Of course, it is possible to analyze causes based on information in which different temporal expression is adopted, by using production condition maps according to Embodiments 3 to 8, which will be described later, in combination with this configuration.

### Embodiment 1

The following describes a management system including a manager terminal according to Embodiment 1 of the present invention in more detail using the diagrams.

(System Configuration)

FIG. 1 schematically shows a configuration example of a production facility in a surface mount production line for printed circuit boards according to the present embodiment. Surface mount technology (SMT) is technology for soldering electronic components onto the surface of printed circuit boards, and the surface mount production line includes mainly three steps, namely solder printing, components mounting, and reflow soldering (solder fusing).

As shown in FIG. 1, the surface mount production line is provided with, from upstream to downstream, a solder printing apparatus X1, a mounter X2, and a reflow furnace X3, which are production apparatuses. The solder printing apparatus X1 is an apparatus that prints solder in paste form onto electrodes (which are referred to as “lands”) on printed circuit boards by using screen printing. The mounter X2 is an apparatus for picking up electronic components that are to be mounted onto circuit boards, and placing the components onto the corresponding portions of solder paste, and is also referred to as a “chip mounter”. The reflow furnace X3 is a heating apparatus for heating and fusing solder paste, then cooling the solder paste, thereby soldering the electronic components onto the circuit boards. In a case where there are many electronic components to be mounted onto circuit boards or there are many types of electronic components to be mounted onto circuit boards, a plurality of mounters X2 may be provided in the surface mount production line.

The surface mount production line is provided with a system that inspects the state of a circuit board at the exit of each of the steps of solder printing, components mounting, and reflow soldering, and automatically detects a fault or the possibility of a fault. The system automatically separates non-defective products from defective products, and also has a function of providing feedback that is based on the inspection results and the analysis results thereof to the operations of each production apparatus (e.g., a function of changing a mount program).

A solder printing inspection apparatus Y1 is an apparatus for inspecting the printing state of solder paste on circuit boards conveyed from the solder printing apparatus X1. The solder printing inspection apparatus Y1 performs two-dimensional or three-dimensional measurement of solder paste printed on circuit boards, and determines whether or not each of various inspection items has a normal value (within a permissible range) based on the results of measurement. Examples of the inspection items include the volume, area, height, degree of displacement, and shape of solder. An image sensor (a camera) can be used for two-dimensional measurement of solder paste, for example, and a laser displacement meter, a phase shifting method, a space encoding method, or a light-section method can be used for three-dimensional measurement, for example.

A component inspection apparatus Y2 is an apparatus for inspecting the state of arrangement of electronic components on circuit boards conveyed from the mounter X2. The component inspection apparatus Y2 two-dimensionally or three-dimensionally measures components (or portions of components, such as the main bodies of the components, or electrodes) that are placed on solder paste, and determines whether or not each of various inspection items has a normal value (within a permissible range) based on the results of measurement. Examples of the inspection items include positional displacement and angular (rotational) displacement of the components, missing components (components are not arranged), wrong components (i.e., incorrect components are arranged), wrong polarity (i.e., the polarities of the electrodes on the components and the circuit board are incorrect), upside-down components (the components are arranged upside down), and the height of the components. Similarly to solder printing inspection, an image sensor (a camera) can be used for two-dimensional measurement of electronic components, for example, and a laser displacement meter, a phase shifting method, a space encoding method, or a light-section method can be used for three-dimensional measurement, for example.

An appearance inspection apparatus Y3 is an apparatus for inspecting the quality of soldering on circuit boards conveyed from the reflow furnace X3. The appearance inspection apparatus Y3 performs two-dimensional or three-dimensional measurement of solder portions that have been subjected to reflow soldering, and determines whether or not each of various inspection items has a normal value (within a permissible range) based on the results of measurement. Examples of the inspection items include the condition of the shape of solder fillets, in addition to the items for component inspection. For measurement of the shape of solder, a so-called color highlight method (i.e., a method in which a solder surface is irradiated with R, G, and B light rays at different incident angles, images of the reflected light rays having the respective colors are captured using a vertical camera, and thus the three-dimensional shape of solder is detected as two-dimensional hue information) may be used instead of the laser displacement meter, the phase shifting method, the space encoding method, and the light-section method described above, for example.

An X-ray inspection apparatus Y4 is an apparatus for inspecting the state of soldering on circuit boards by using an X-ray image. For example, in the case of packaged components or multi-layer circuit boards, such as a ball grid array (BGA) or a chip size package (CSP), solder joints are hidden under the components or the circuit boards, and it is impossible to inspect the state of solder by using the appearance inspection apparatus Y3 (i.e., by using an image of the external appearance). The X-ray inspection apparatus Y4 is an apparatus that complements such shortcomings of external appearance inspection. Examples of the inspection items for the X-ray inspection apparatus Y4 include positional displacement of the components, the solder height, the solder volume, the solder ball diameter, the length of back fillets, and the condition of solder joints. Note that an X-ray transmission image may be used as an X-ray image, and the use of a computed tomography (CT) image is also preferable.

(Management Apparatus)

The production apparatuses X1 to X3 and the inspection apparatuses Y1 to Y4 described above are connected to a management apparatus 100 via a network (LAN). The management apparatus 100 is constituted by a general-purpose computer system that manages and controls the production apparatuses X1 to X3 and the inspection apparatuses Y1 to Y4, and includes a CPU (a processor), a main storage device (a memory), an auxiliary storage device (a hard disk or the like), input devices (a keyboard, a mouse, a controller, a touch panel, etc.), a display device, and the like, which are not shown. Functions of the management apparatus 100, which will be described later, are realized as a result of the CPU reading and executing a program stored in the auxiliary storage device.

Note that the management apparatus 100 may be constituted by a single computer or a plurality of computers. Alternatively, all or some of the functions of the management apparatus 100 may be implemented by a computer included in any of the production apparatuses X1 to X3 and the inspection apparatuses Y1 to Y4. Alternatively, some of the functions of the management apparatus 100 may be realized by a server (for example, a cloud server) on the network.

A manager terminal 10, an operator terminal 20, and a program management server 40 are connected to the management apparatus 100 via a network (LAN). The program management server 40 manages inspection/mount programs 50. The inspection/mount programs 50 are actually programs for controlling the production apparatuses X1 to X3 and the inspection apparatuses Y1 to Y4, respectively, and are stored in a predetermined storage region of the program management server 40, downloaded into the production apparatuses X1 to X3 and the inspection apparatuses Y1 to Y4 as necessary, stored in predetermined storage regions of the respective apparatuses, and executed by the respective apparatuses.

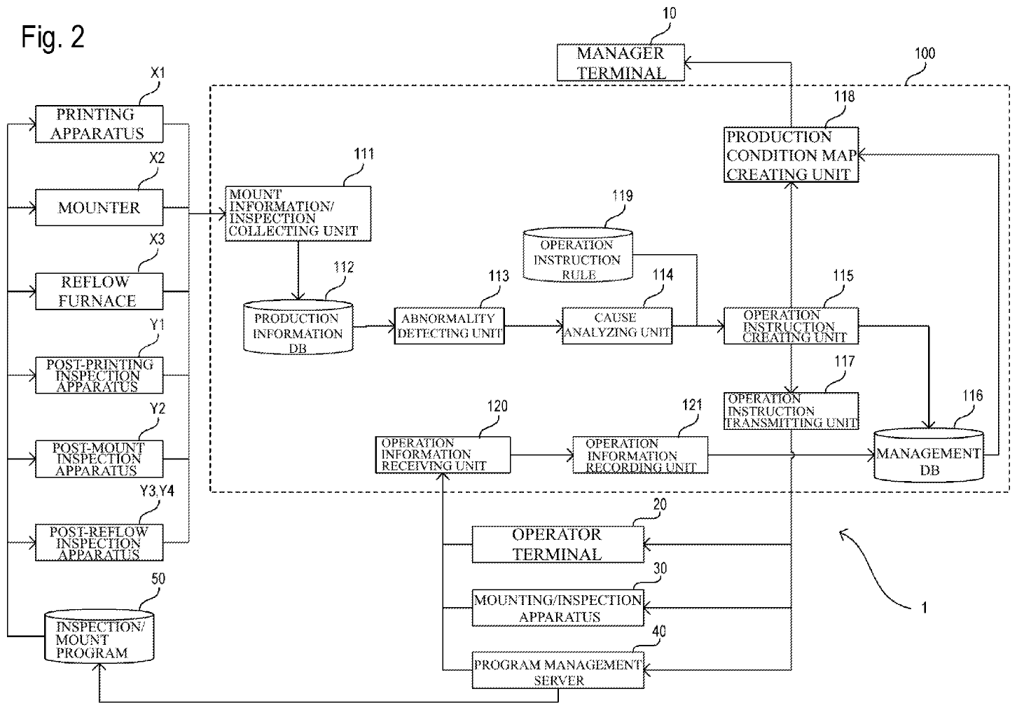

The management apparatus 100 of the present embodiment includes functional units for realizing functions that enable the manager of a production facility to efficiently perform maintenance of the facility and quality control. FIG. 2 shows a block diagram of the functional units included in the management apparatus 100.

As shown in FIG. 2, the management apparatus 100 includes a mount information/inspection result collecting unit 111, a production information database 112, an abnormality detecting unit 113, a cause analyzing unit 114, an operation instruction creating unit 115, a management database 116, an operation instruction transmitting unit 117, a production condition map creating unit 118, an operation instruction rule 119, an operation information receiving unit 120, and an operation information recording unit 121.

The mount information/inspection result collecting unit 111 collects mount information including information regarding circuit boards, solder, and components such as various electronic components, which are used in the production apparatuses X1 to X3, and information regarding various members and mechanisms of the production apparatuses X1 to X3, and also collects inspection results from the inspection apparatuses Y1 to Y4. In particular, information of cases where there is an abnormality is collected as the inspection results. Here, cases where there is an abnormality include not only cases where there is a “real fault” that is determined as a fault by any of the inspection apparatuses Y1 to Y4 and also determined as a fault through visual inspection, but also so-called “overkill” cases where a product is determined as a defective product by any of the inspection apparatuses Y1 to Y4 but is determined as a “non-defective product” through visual inspection. Note that information of an abnormality is associated with mount information regarding an apparatus member or a component in which the abnormality occurred. The inspection results also include information of errors detected in the steps performed by the production apparatuses X1 to X3. Information of such an error is also associated with mount information regarding an apparatus member or a component in which the error occurred.

The production information database 112 is a database in which the mount information and the inspection results collected by the mount information/inspection result collecting unit 111 are recorded in association with each other with respect to the same circuit board, the same component, the same date and time, or the like.

The abnormality detecting unit 113 detects an abnormality in any component on printed circuit boards based on information recorded in the production information database 112. Here, the presence or absence of an abnormality is detected based on continuous occurrence or the rate of occurrence of real faults, for example.

The site of the abnormality and conditions of the abnormality are recorded in the management database 116 in association with production conditions.

The cause analyzing unit 114 analyzes causes of the abnormality detected by the abnormality detecting unit 113.

The operation instruction creating unit 115 creates an operation instruction for solving the abnormality based on the operation instruction rule 119 in accordance with the causes of the abnormality found through analysis by the cause analyzing unit 114. Examples of operation instructions relating to the printing apparatus X1 include mouth cleaning, solder replenishment, and mask position change or correction. The content of operation instructions is not limited to these examples. The content of operation instructions relating to the mounter will be described later.

The operation instruction created by the operation instruction creating unit 115 is recorded in the management database 116 together with the site and conditions of the abnormality. Also, the operation instruction created by the operation instruction creating unit 115 is transmitted via the operation instruction transmitting unit 117 to at least any of the operator terminal 20, mounting/inspection apparatuses 30, and the program management server 40 in accordance with the content of the operation instruction. That is, an operation instruction directed to an operator is transmitted to the operator terminal 20, an operation instruction for controlling an apparatus is transmitted to the target apparatus included in the mounting/inspection apparatuses 30, and an operation instruction for changing a parameter in a program is transmitted to the program management server 40. Here, the production apparatuses X1 to X3 and the inspection apparatuses Y1 to Y4 are collectively referred to as the mounting/inspection apparatuses 30, and an operation instruction is actually transmitted to at least any of these apparatuses.

Operation information regarding the operation instruction transmitted from the operation instruction transmitting unit 117 to the operator terminal 20, any of the mounting/inspection apparatuses 30, or the program management server 40 is transmitted from the operator terminal 20, the mounting/inspection apparatus 30, or the program management server 40 to the operation information receiving unit 120.

The operation corresponding to the operation instruction transmitted from the operation instruction transmitting unit 117 to the operator terminal 20, the mounting/inspection apparatus 30, or the program management server 40 is not always performed.

For example, an operator may have no time to check the operation instruction transmitted to the operator terminal 20. Also, the operator may have no time to perform the operation although the operator recognized the operation instruction received by the operator terminal 20. Also, the target of the operation instructed via the operator terminal 20 may be absent due to the produced model having been changed or replaced by changeover.

As for the operation instruction transmitted to the mounting/inspection apparatus 30, the target of the instructed operation may be absent due to the produced model having been changed or replaced by changeover. Also, there may be a case where the instructed operation cannot be performed because, when the use of a device ID is stopped, there is no alternative to it and the production will stop, or it is not desirable to stop the production line, for example. Also, the instructed operation may be rejected by a determination unit of the mounting apparatus.

As for the operation instruction transmitted to the program management server 40, the version of a mount program or component library that is the target of the instructed operation may not match the content of the instruction. Also, the mount program or component library that is the target of the instructed operation may have been locked and be unchangeable. Also, the instructed operation may be rejected by a determination unit of the program management server.

The operation information received by the operation information receiving unit 120 from the operator terminal 20, the mounting/inspection apparatus 30, or the program management server 40 is recorded in the management database 116 by the operation information recording unit 121 in association with the site of the abnormality corresponding to the operation content.

The production condition map creating unit 118 creates a production condition map based on the operation instruction created by the operation instruction creating unit 115 and the information recorded in the management database 116. Specifically, the production condition map is data that constitutes a production condition map display screen displayed in a production condition map display unit 12 of the manager terminal 10.

The production condition map created by the production condition map creating unit 118 is transmitted to the manager terminal 10 and is displayed.

(Manager Terminal)

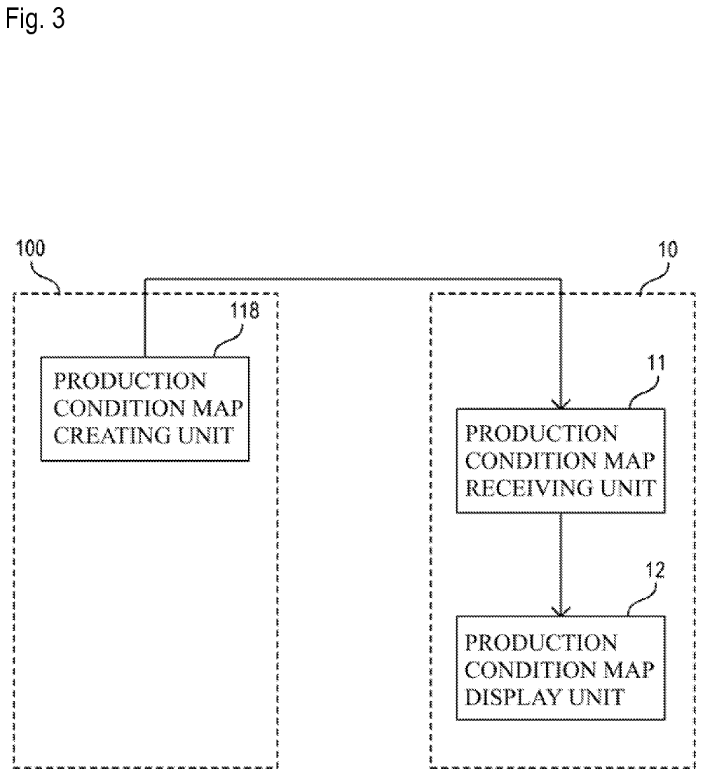

As shown in FIG. 3, the manager terminal 10 includes a production condition map receiving unit 11 and the production condition map display unit 12. The manager terminal 10 is constituted by a general-purpose computer system that includes a CPU (a processor), a main storage device (a memory), an auxiliary storage device (a hard disk or the like), input devices (a keyboard, a mouse, a controller, a touch panel, etc.), a display device, and the like. The functional units of the manager terminal 10 described above are realized as a result of the CPU reading and executing a program stored in the auxiliary storage device.

The production condition map receiving unit 11 receives the production condition map created by the production condition map creating unit 118 of the management apparatus 100.

The production condition map display unit 12 displays the production condition map received by the production condition map receiving unit 11. Specifically, the production condition map display unit 12 is constituted by a display device such as a display, and may also serve as an input device like a touch panel display.

(Operator Terminal)

Here, an instruction to perform an operation is given to an operator via the operator terminal 20, and the operator executes the operation.

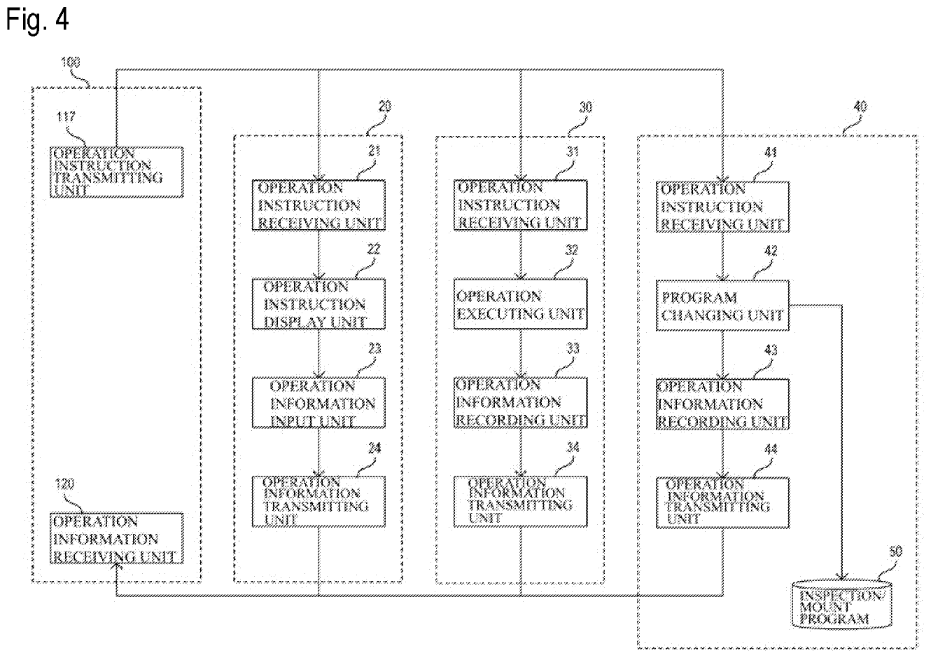

As shown in FIG. 4, the operator terminal 20 includes an operation instruction receiving unit 21, an operation instruction display unit 22, an operation information input unit 23, and an operation information transmitting unit 24. Specifically, the operator terminal 20 corresponds to various apparatuses such as an inspection program creating terminal, a mount program creating terminal, a maintenance operation terminal, or a line management terminal according to the operator and the operation content. Such an operator terminal 20 may be constituted by a general-purpose computer system that includes a CPU (a processor), a main storage device (a memory), an auxiliary storage device (a hard disk or the like), input devices (a keyboard, a mouse, a controller, a touch panel, etc.), a display device, and the like. Alternatively, all or some of the functions of the operator terminal 20 may be implemented by a computer included in any of the production apparatuses X1 to X3 and the inspection apparatuses Y1 to Y4.

The operation instruction receiving unit 21 receives an operation instruction transmitted from the operation instruction transmitting unit 117 of the management apparatus 100.

The operation instruction display unit 22 displays the operation instruction received by the operation instruction receiving unit 21. Specifically, the operation instruction display unit 22 is constituted by a display device such as a display, and may also serve as an input device like a touch panel display.

Operation information corresponding to the operation instruction is input via the operation information input unit 23. Specifically, the operation information input unit 23 is constituted by an input device that enables input of operation information corresponding to an operation instruction displayed in the display device, and may also serve as the display device like a touch panel display.

The operation information input via the operation information input unit 23 is transmitted from the operation information transmitting unit 24 to the operation information receiving unit 120 of the management apparatus 100.

(Mounting/Inspection Apparatus)

Here, a mounting/inspection apparatus 30 automatically executes an instructed operation.

As shown in FIG. 4, the mounting/inspection apparatus 30 includes an operation instruction receiving unit 31, an operation executing unit 32, an operation information recording unit 33, and an operation information transmitting unit 34. As described above, the mounting/inspection apparatus 30 is a generic term for the production apparatuses X1 to X3 and the inspection apparatuses Y1 to Y4 and actually corresponds to at least any of these apparatuses in accordance with the content of the operation instruction.

The operation instruction receiving unit 31 receives an operation instruction transmitted from the operation instruction transmitting unit 117 of the management apparatus 100.

The operation executing unit 32 executes the instructed operation on a member or a mechanism constituting the target apparatus based on the operation instruction received by the operation instruction receiving unit 31.

The operation information recording unit 33 records operation information regarding the operation executed by the operation executing unit 32.

The operation information recorded by the operation information recording unit 33 is transmitted from the operation information transmitting unit 34 to the operation information receiving unit 120 of the management apparatus 100.

(Program Management Server)

Here, the program management server 40 automatically executes an instructed operation.

As shown in FIG. 4, the program management server 40 includes an operation instruction receiving unit 41, a program changing unit 42, an operation information recording unit 43, and an operation information transmitting unit 44.

The operation instruction receiving unit 41 receives an operation instruction transmitted from the operation instruction transmitting unit 117 of the management apparatus 100.

The program changing unit 42 changes an inspection/mount program 50 based on the operation instruction received by the operation instruction receiving unit.

The operation information recording unit 43 records operation information regarding the state of change made in the program by the program changing unit 42.

The operation information recorded by the operation information recording unit 43 is transmitted from the operation information transmitting unit 44 to the operation information receiving unit 120 of the management apparatus 100.

(Mounter)

The following describes operations of the functional units of the management apparatus 100, the manager terminal 10, and the operator terminal 20 in detail using an example of the mounter X2.

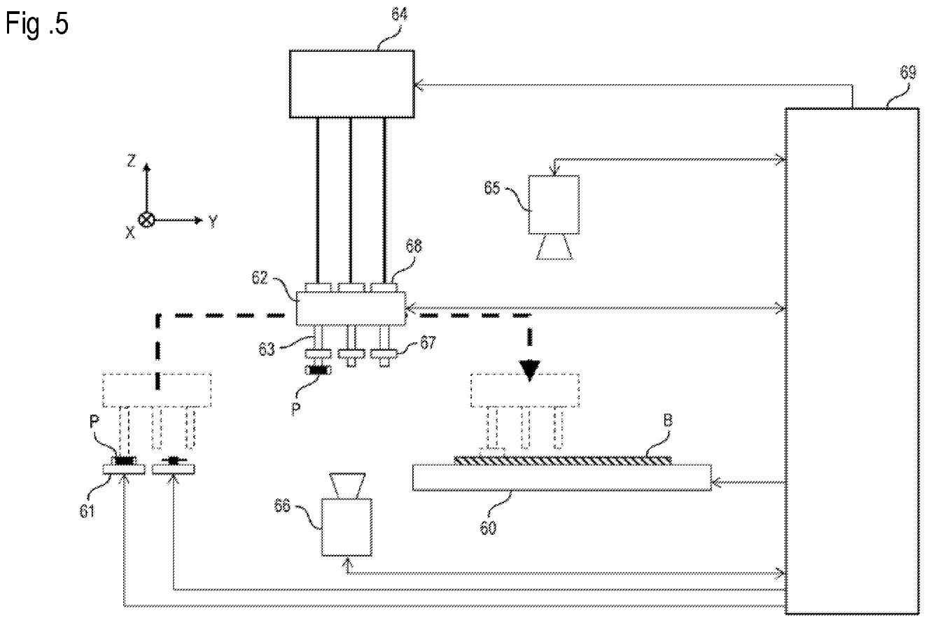

FIG. 5 is a diagram schematically showing the configuration of the mounter X2. The mounter X2 includes a stage 60 for placing a circuit board B, a plurality of feeders 61 that supply electronic components P, a movable head 62 that picks up the electronic components P, a plurality of nozzles 63 attached to the head 62, and a vacuum pump 64 that controls air pressures of the respective nozzles, for example. Electronic components P having different component numbers are set on the feeders 61 in respective rows. Also, the mounter X2 includes, as an observation system for detecting an abnormality in the operations of the mounter X2, an upper camera 65, a lower camera 66, a contact sensor 67 for measuring contact pressures at end surfaces of the nozzles, and a pressure sensor 68 for measuring air pressures of the nozzles, for example. A control unit 69 is a block that controls each part of the mounter X2 and performs computation and information processing, and includes a CPU (a processor) and a memory, for example. The mounter X2 may also include an output device for outputting information. As for the coordinate system, the X axis and the Y axis are parallel to a circuit board surface, and the Z is perpendicular to the circuit board surface.

When a circuit board B is conveyed to the stage 60, the control unit 69 controls each nozzle 63 following the mount program to pick up and convey necessary electronic components P from the feeders 61 and sequentially arrange the electronic components P on the circuit board B. When all the electronic components P are arranged (mounted), the circuit board B is conveyed to a downstream step (the inspection apparatus Y2). Also, production log information including production abnormality information is recorded as production information regarding the circuit board B in the memory of the mounter X2. A circuit board ID, component numbers of the components, a circuit number, and information (nozzle IDs and feeder IDs) indicating apparatus members used to process the components are associated with each other in the production log information.

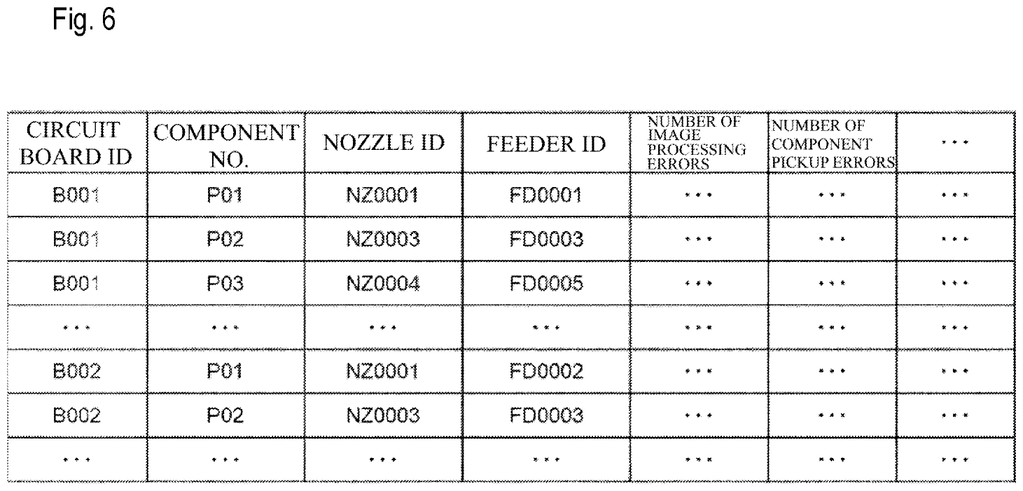

FIG. 6 shows an example of the production log information recorded in the mounter X2. Each row corresponds to a production record of a component and includes information such as a circuit board ID, a component number, a circuit number, a nozzle ID, a feeder ID, and production abnormality information (the number of image recognition processing errors and the number of component pickup errors). It is possible to know apparatus members used to produce a component on a circuit board by referring to the production log information.

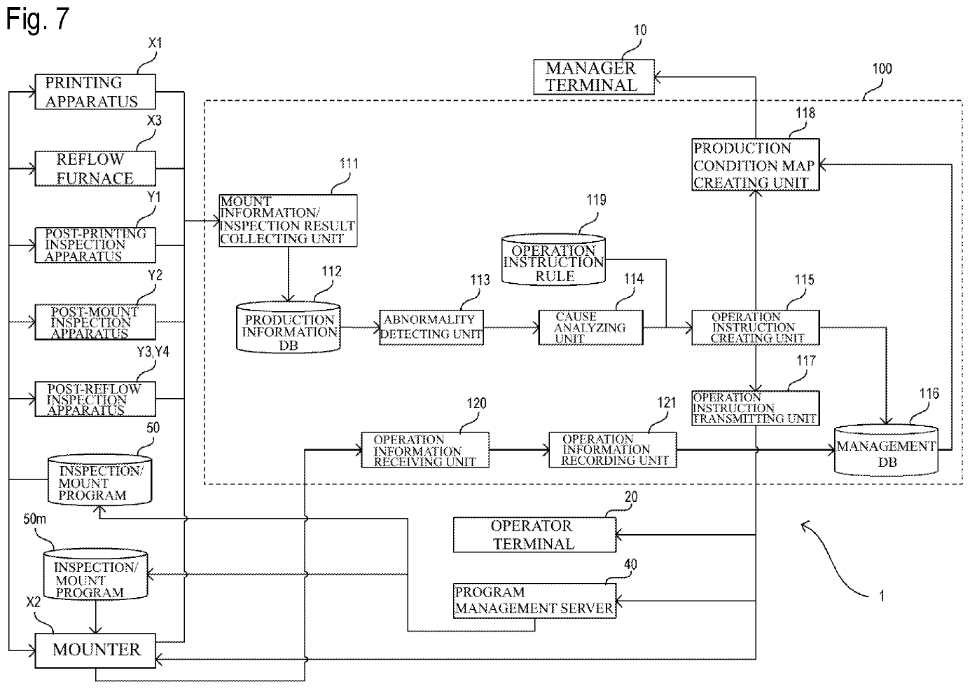

FIG. 7 is a functional block diagram of the management apparatus 100 clarifying a configuration relating to the mounter X2. Functional blocks that are common to the functional block diagram shown in FIG. 2 are denoted by the same reference signs as those used in FIG. 2, and a detailed description thereof is omitted. Here, an inspection/mount program 50m is a program relating to the mounter X2 out of the inspection/mount programs 50.

The mount information/inspection result collecting unit 111 collects information regarding components such as various electronic components, circuit boards, and solder used in the production line and information regarding various members and mechanisms constituting the production apparatuses such as the mounter X2, and also collects the production log information (production abnormality information included therein) described above from the mounter X2 and information of inspection results (in particular, information of real faults and overkill) about circuit boards after mounting from the post-mount inspection apparatus Y2. These pieces of information may be collected at suitable timings. For example, these pieces of information may be obtained at a point in time determined in advance or at a frequency determined in advance, or in response to a request from a user. Information regarding components can be collected when a new component is introduced into the production line, or a component having the same component number as those already used but produced in a different production lot is introduced into the production line, for example. Information regarding various members and mechanisms can be collected at the time of replacement or maintenance of an apparatus member, or introduction of a new apparatus member into the production line, for example. The production log information can be transmitted from the control unit 69 of the mounter X2 to the management apparatus 100 every time mounting of components on a circuit board is completed by the mounter X2, for example. Information of inspection results can be collected every time inspection of a circuit board is completed by the post-mount inspection apparatus Y2, for example.

The abnormality detecting unit 113 detects an abnormality such as an error in the production of a component or a fault found in the inspection from information collected by the mount information/inspection result collecting unit 111 and recorded in the production information database 112.

The cause analyzing unit analyzes causes of the abnormality detected by the abnormality detecting unit 113, and extracts an apparatus member, a component number, or a parameter in a program that is presumed to be the cause of the abnormality. There is no particular limitation on the timing and method for analyzing causes, but the causes may be analyzed in every predetermined totaling period based on comparison between the number of abnormalities detected for each apparatus member or component number and a normal value or comparison between numbers of abnormalities detected for different members of the same type or different component numbers, for example.

The operation instruction creating unit 115 creates an operation instruction based on the cause of the abnormality analyzed by the cause analyzing unit 114 and the operation instruction rule 119 prescribed in advance to solve abnormalities in accordance with causes of the abnormalities.

The following describes examples of operation instructions. Examples of operation instructions for the mounter X2 include an instruction to stop the use of a specific nozzle or feeder. Examples of operation instructions for the program management server 40 include: instructions relating to the mounter X2 such as an instruction to change or correct the mount coordinates and an instruction to change the size of a component or a permissible range; and instructions relating to the post-mount inspection apparatus Y2 such as an instruction to change inspection standards. Examples of operation instructions given to the operator via the operator terminal 20 include an instruction to replace a nozzle, a feeder, or the head, an instruction to perform maintenance thereof, and an instruction to perform an operation that cannot be automatically performed by the mounter X2 or the post-mount inspection apparatus Y2. The content of operation instructions is not limited to these examples.

A production condition map created based on the information recorded in the management database 116 is transmitted from the production condition map creating unit 118 to the manager terminal 10 and is displayed in the production condition map display unit 12.

(Screen for Manager (Production Condition Map Display Screen))

FIG. 8 shows an example of the production condition map display screen 70 displayed in the production condition map display unit 12 of the manager terminal 10. In FIG. 8, leader lines associated with reference numerals are drawn as broken lines to distinguish them from lines displayed in the screen.

In this production condition map, aggregate results of respective types of faults and errors detected by or occurring in the mounting apparatuses and the inspection apparatuses are displayed in time series.

The production condition map display screen 70 includes the main part 71 and the legend part 72. The names of items “Program” 731, “PCB ID” 732, and “Time” 733 are displayed in the upper left field 73 of the main part 71, and information corresponding to these items is displayed in the upper right field 74. The name of a program such as “MPRG1501” is displayed as the item “Program” 731, which represents program name. Circuit board IDs of circuit boards displayed in the production condition map display screen, such as “PCBA001”, “PCBA021”, “PCBA041”, and “PCBA061” are displayed as the item “PCB ID” 732, which represents circuit board ID for identifying each circuit board. Information regarding 58 circuit boards is displayed in the production condition map display screen 70 shown in FIG. 8. Accordingly, due to limitations of the display space, a predetermined number of (e.g., 20) circuit boards are treated as a group, and circuit board IDs of the circuit boards included in the group are represented by the circuit board ID of the first circuit board in that group. Alternatively, it is also possible to treat circuit boards that are processed in 5 minutes from a representative time point such as the mount time point in the first mounter as a group. It is also possible to display circuit board IDs of all circuit boards depending on the number of circuit boards. The item “Time” 733 shows mount time points of the circuit boards having the circuit board IDs displayed as the item “PCB ID” 732. Here, a time point at which the corresponding circuit board was loaded into the first apparatus among the plurality of apparatuses is displayed as the mount time point of the circuit board. As the item “Time” 733, “2020-10-15 08:36:58” is displayed for the circuit board “PCBA001”, “2020-10-15 09:03:02” is displayed for the circuit board “PCBA021”, and “2020-10-15 09:27:07” is displayed for the circuit board “PCB041”.

The names of mounting apparatuses and inspection apparatuses included in a single line are displayed in the header column 75 of the lower left field of the production condition map display screen. Here, “CM-003-1” to “CM-003-6”, which are mounters, “PREAOI-003”, which is a post-mount inspection apparatus, and “POSTAOI-003” and “AXI-003”, which are post-reflow inspection apparatuses, are displayed in the header column 75. Device IDs may also be displayed instead of the names of apparatuses. The arrangement order of the names of apparatuses in the header column 75 can be set as appropriate. Although the names of apparatuses may be arranged in the order of the steps from the top to the bottom in the header column 75, in this case, the mounters 751 and the inspection apparatuses 752 are displayed separately, and the post-mount inspection apparatus and the post-reflow inspection apparatuses are displayed as the inspection apparatuses 752. The mounting apparatuses and the inspection apparatuses displayed in the header column 75 correspond to production members in the present invention.

A plurality of vertically elongated rectangular marks are displayed in the lower right field 76 of the main part 71 of the production condition map display screen 70. Here, each mark represents a circuit board (hereinafter, marks representing circuit boards will also be referred to as “circuit boards”). Circuit boards that are arranged in the lower right field 76 in the same row as an apparatus displayed in the header column 75 indicate that the circuit boards represented by those marks are mounting targets of that apparatus. A plurality of circuit boards arranged in the same row are arranged in the order in which the circuit boards were subjected to mounting. That is, each circuit board among the plurality of circuit boards was subjected to mounting by the apparatus later than circuit boards arranged on the left side thereof. When focusing on a specific apparatus displayed in the header column 75, for example, the mounter CM-003-1, a time axis Ta1 (not displayed) defined for the mounter CM-003-1 extends in such a manner that time progresses rightward, and a plurality of circuit boards B1a, B2a, B3a, . . . are arranged along the time axis Ta1. The plurality of circuit boards B1a, B2a, B3a, etc., arranged in the same row are equally spaced apart from each other in the row direction, but this arrangement merely indicates a temporal order, and does not indicate intervals between time points at which the circuit boards B1a, B2a, B3a, etc., were processed. There is no limitation to this temporal expression, and the plurality of circuit boards B1a, B2a, B3a, etc., may be arranged in the row direction at intervals corresponding to intervals between the time points at which the circuit boards were processed. Also, timings of events, which are any of 4M changes that occurred in the apparatus, are displayed in time series in the row direction as event information E1 and the like, which are represented by rectangles thinner than the circuit boards, together with the circuit boards processed by the apparatus. Out of the plurality of circuit boards and the like displayed in the lower right field 76 of the main part 71 of the production condition map display screen 70, circuit boards arranged in the same column represent the same circuit board. That is, a plurality of circuit boards arranged in the same column represent the same circuit board subjected to mounting in respective steps performed by the plurality of apparatuses displayed in the header column 75. For example, the circuit board B1a displayed in the first column in the first row of the lower right field 76, a circuit board B1b displayed in the first column in the third row from the bottom, a circuit board B1c displayed in the first column in the second row from the bottom, and a circuit board B1d displayed in the first column in the bottom row represent the same circuit board identified by the circuit board ID PCBA001. Here, the circuit boards correspond to products in the present invention (this also applies to embodiments described below). Here, a unit product in the present invention is constituted by a single product, and accordingly, each rectangular mark corresponds to a single circuit board. However, the unit product in the present invention may also be constituted by a plurality of products, and accordingly, each rectangular make may also correspond to one or more circuit boards.

The numbers of faults and errors occurring in or detected for a circuit board in a step performed using the apparatus displayed in the header column 75 in the same row as the circuit board are displayed as a cumulative bar graph that shows the numbers of respective types of errors and faults and overlaps with the circuit board displayed in the lower right field 76 of the main part 71 of the production condition map display screen 70. For example, a bar graph Q1 showing the number of component pickup errors detected when the circuit board B2a was subjected to mounting in the mounter CM-003-1 is displayed in such a manner as to overlap with the circuit board B2a displayed in the first row of the lower right field 76. Also, a bar graph Q2 showing the number of image recognition errors detected when the circuit board B4a was subjected to mounting in the mounter CM-003-1 is displayed in such a manner as to overlap with the circuit board B4a, which is also displayed in the first row. Furthermore, a cumulative bar graph composed of a bar graph Q3 and a bar graph Q4 respectively showing the number of component pickup errors and the number of image recognition errors detected when the circuit board B6a was subjected to mounting is displayed on the circuit board B6a, which is also displayed in the first row. With respect to each step for inspecting circuit boards, a cumulative bar graph showing the numbers of respective types of faults and errors occurring in or detected for a circuit board is displayed in such a manner as to overlap with the circuit board. For example, a bar graph Q5 showing the number of detected real faults is displayed in such a manner as to overlap with a circuit board B6b inspected by the post-mount inspection apparatus PREAOI-003 displayed in the third row from the bottom in the header column 75. Also, a bar graph Q6 showing the number of overkill cases detected in the inspection performed by the post-mount inspection apparatus PREAOI-003 is displayed in such a manner as to overlap with a circuit board B8b displayed in the same row.

The legend part 72 including a legend that shows correspondence between types of errors, faults, etc., displayed in such a manner as to overlap with circuit boards and display manners thereof is displayed below the main part 71 of the production condition map display screen 70. Here, the mounters and the inspection apparatuses are displayed in the header column 75 of the main part 71 of the production condition map display screen 70, and therefore, types of errors and faults are distinguished by displaying image recognition errors 761 in the mounters with hatching extending diagonally up to the left, displaying component pickup errors 762 in the mounters with hatching extending diagonally up to the right, displaying overkill cases 763 in the inspection apparatuses in grey, and displaying real faults 764 in black. Actually, these types of faults and errors are displayed in different colors. The legend further includes indication of correspondence 766 between the number of errors and the height of a bar graph showing the number of errors, correspondence 767 between the number of components mounted on a circuit board and a display manner of the circuit board, and correspondence 768 between the type of an event (for example, reel attachment) and a display manner of a rectangle representing event information. A configuration is also possible in which a description of the correspondence between display manners and display content is displayed as a popup when the corresponding display on the screen is selected by being clicked or touched.

The following describes production conditions displayed in the production condition map display screen 70 shown in FIG. 8.

Here, the circuit board B1a and the like displayed in the top row of the lower right field 76 are mounting targets of only the mounter CM-003-1 out of the plurality of mounters CM-003-1 to CM-003-6 displayed in the header column 75, and are not mounting targets of the mounters CM-003-2 to CM-003-6. Therefore, in the second to sixth rows where the mounters CM-003-2 to CM-003-6 are displayed in the header column 75, circuit boards are not displayed in the same columns as the circuit board B1a and the like arranged in the first row.

In FIG. 8, the event information E1 arranged on the left side of the circuit board B1a in the first row of the lower right field 76, which corresponds to the mounter CM-003-1, represents replacement of a feeder. For example, a case is conceivable where a feeder provided with a new reel was prepared because components were going to run short, then all components were used up from a reel on a feeder attached to the mounter, and the feeder was replaced with the prepared feeder.

The cumulative bar graphs displayed in such a manner as to overlap with the circuit board B1a and the like arranged on the right side of the event information E1 in the first row of the lower right field 76 in the production condition map display screen 70 indicate frequent occurrence of component pickup errors. Also, the cumulative bar graphs displayed in such a manner as to overlap with the circuit boards B1b, B1c, etc., arranged in the same rows as the post-mount inspection apparatus PREAOI-003 and the post-reflow inspection apparatus POSTAOI-003 indicate frequent occurrence of real faults.

The event information E2 indicates that, under the above circumstances, an operation instruction to check the attached state of the reel on the newly-attached feeder was issued and the reel on the feeder attached to the mounter CM-003-1 was once removed and again attached based on the operation instruction. It can be found that, as a result, the conditions were improved, and component pickup errors and real faults did not occur after the reel was reattached.

As described above, in the production condition map display screen 70, the circuit board B1a and the like, which are mounting targets, are arranged in the time axis direction with respect to each apparatus constituting the printed circuit board mount production line, the time series of respective apparatuses are aligned, and aggregate results of respective types of errors are displayed in time series by being overlaid on the circuit board B1a and the like arranged in this manner. Therefore, it is possible to narrow down causes of an abnormality based on simultaneously occurring faults and errors. Also, it is possible to find time dependency such as whether or not faults and errors occurred simultaneously, successively, in a concentrated manner, or sporadically. Therefore, it is possible to determine whether it is necessary to take measures at the present time or there is no longer a need to take measures. Also, event information is arranged and displayed along the time series where the circuit board B1a and the like are arranged, and therefore, it is possible to find causes of errors and measures that were effective to improve the conditions, for example. As described above, when a plurality of types of faults and errors occurred or are detected, it is possible to analyze causes and determine measures in a short time with use of the production condition map display screen 70.

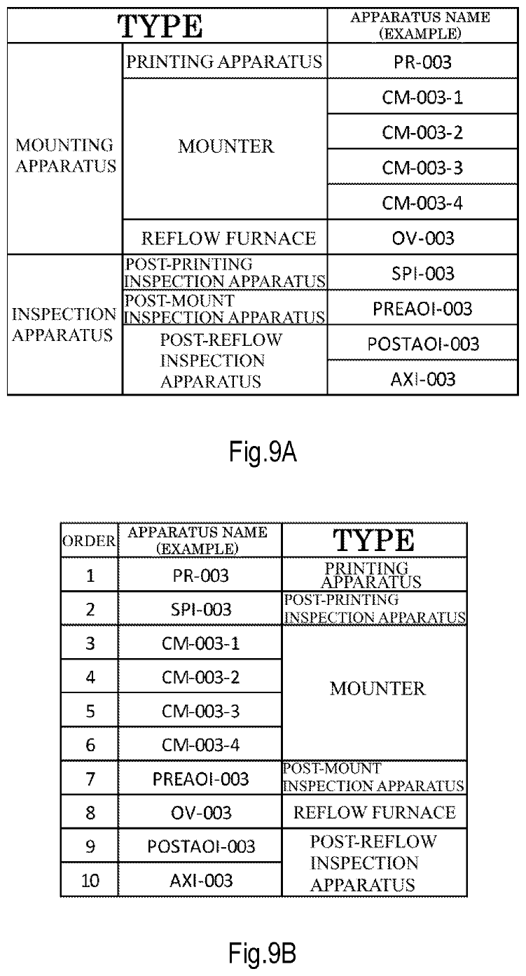

The apparatuses displayed in the lower left field of the production condition map display screen are not limited to the examples shown in FIG. 8. As shown in FIG. 9A, the apparatuses constituting the printed circuit board mount production line may be arranged from the top to the bottom based on the types of apparatuses. For example, the mounting apparatuses and the inspection apparatuses are arranged in this order from the top to the bottom. The mounting apparatuses are arranged in the order of the printing apparatus PR-003, the mounters CM-003-1 to CM-003-4, and the reflow furnace OV-003 from the top to the bottom. The inspection apparatuses are arranged in the order of the post-printing inspection apparatus SPI-003, the post-mount inspection apparatus PREAOI-003, and the post-reflow inspection apparatuses POSTAOI-003 and AXI-003 from the top to the bottom.

Also, the apparatuses displayed in the lower left field of the production condition map display screen may be arranged in an order in which circuit boards are loaded in the printed circuit board mount production line as shown in FIG. 9B. For example, the apparatuses are arranged in the order of the printing apparatus PR-003, the post-printing inspection apparatus SPI-003, the mounters CM-003-1 to CM-003-4, the post-mount inspection apparatus PREAOI-003, the reflow furnace OV-003, and the post-reflow inspection apparatuses POSTAOI-003 and AXI-003 from the top to the bottom.

It is also possible to display the number of cases where shortage of solder, which is an error relating to the printing apparatus, occurred, as the number of errors displayed in such a manner as to overlap with the circuit board B1a and the like in the production condition map display screen 70 shown in FIG. 8. It is also possible to display the number of cases where there was a difference between a set temperature and a measured value as the number of errors relating to the reflow furnace.

The event information displayed in time series together with the circuit boards in the lower right field 76 of the production condition map display screen 70 shown in FIG. 8 is not limited to that described above. Various 4M changes that occur in the printed circuit board mount production line correspond to events.

As for the mounters, there are events relating to a nozzle, a feeder, a head, and a holder. Examples of events relating to a nozzle include replacement of the nozzle. Examples of events relating to a feeder include replacement of a reel with a new reel due to all components having been used, replacement of the feeder with another feeder provided with a new reel, and removal and reattachment of the feeder when the feeder is not appropriately attached to the mounter. Examples of events relating to a head and a holder include maintenance of an air passage. Events relating to the mounters also include temporary stoppage due to an operation performed by an operator and stoppage due to some error.

As events relating to the printing apparatus, it is possible to display replenishment of solder, a change in mounting parameters (an applied pressure, the number of times of squeegeeing, the squeegee speed, etc.) and maintenance.

As an event relating to the reflow furnace, it is possible to display a change in a temperature profile.

Other than the above events, information regarding changeover, a change in the mount program, or suspension of the production may also be displayed as the event information in such a manner as to overlap with the circuit board B1a or the like in the lower right field 76 of the production condition map display screen 70.

As for all of the nozzle, the feeder, the head, and the holder, it is also possible to display maintenance performed in a certain period of time, the number of days elapsed from the maintenance, or the number of times these members were used for mounting, in the production condition map display screen 70, in addition to the information shown in FIG. 8. It is also possible to display component recognition parameters such as the size of the component, a permissible range thereof, the number of terminals, and the color or brightness of the component, models of the nozzle and the feeder used for mounting, and information such as mounting coordinates on a circuit board and a rotation angle, which are included in the mount program.

### Embodiment 2

The following describes a management system including a manager terminal 10 according to Embodiment 2 of the present invention. Except for a production condition map display screen 80 displayed in the production condition map display unit 12, the configuration of Embodiment 2 is common to Embodiment 1, and therefore, the reference numerals used in Embodiment 1 are used for the common configuration, and a detailed description thereof is omitted.

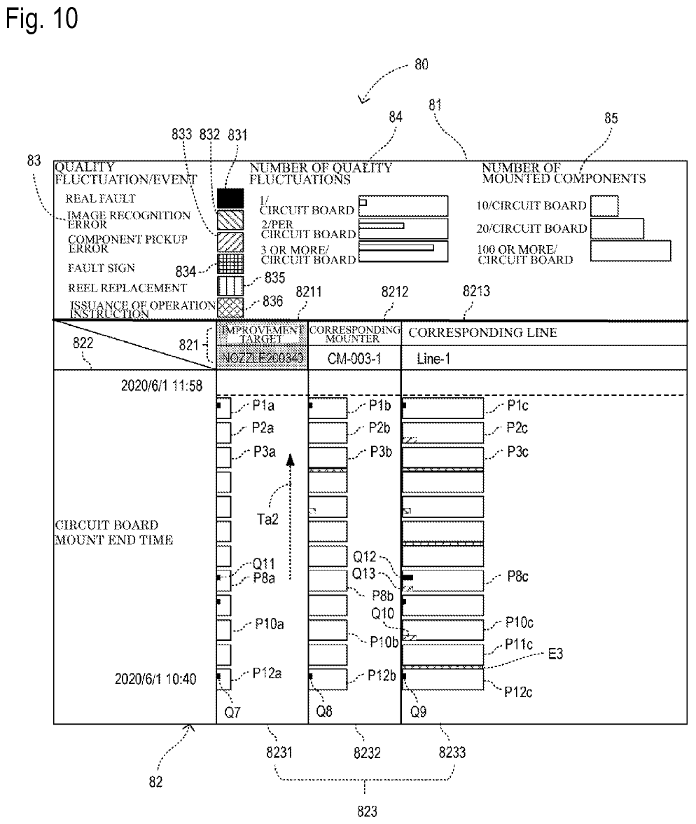

FIG. 10 shows the production condition map display screen 80. In FIG. 10, leader lines associated with reference numerals are drawn as broken lines to distinguish them from lines displayed in the screen.

In this production condition map, aggregate results of respective types of faults and errors detected by or occurring in the mounting apparatuses or the inspection apparatuses are displayed in time series.

A legend part 81 displaying a legend is provided in an upper portion of the production condition map display screen 80, and a main part 82 displaying aggregate results of errors and the like is provided in a lower portion of the production condition map display screen 80.

Correspondence 83 between displayed quality fluctuations and events and display manners thereof is displayed in the legend part 81. Here, information indicating real faults, image recognition errors, component pickup errors, and fault signs is displayed as quality fluctuation information. Real faults 831 are displayed in black, image recognition errors 832 are displayed with hatching extending diagonally up to the left, component pickup errors 833 are displayed with hatching extending diagonally up to the right, and fault signs 834 are displayed with cross hatching. Information indicating replacement of a reel and issuance of an operation instruction is displayed as event information. Replacement of a reel 835 is displayed with vertical strips and issuance of an operation instruction 836 is displayed with diagonal cross hatching. Quality fluctuation information to be displayed can be selected as appropriate in accordance with the improvement target device. Also, event information to be displayed is not limited to the above examples, and various 4M changes can be selected as events as appropriate. The display manners of quality fluctuation information and event information are not limited to the above examples, and different types of information may also be displayed in different colors.

A legend of the number of quality fluctuations 84 is also displayed in the legend part 81. In the main part 82, each horizontally elongated rectangle represents a circuit board, and bars extending in the lateral direction are displayed in the rectangles in such a manner as to overlap with the rectangles. The length of each bar indicates the number of quality fluctuations, and the lengths of bars respectively indicating one quality fluctuation per circuit board, two quality fluctuations per circuit board, and three quality fluctuations per circuit board are shown.

A legend of the number of components (the number of mounted components) 85 mounted on a circuit board is also displayed in the legend part 81. Here, the number of components mounted on a circuit board is indicated by the length in the lateral direction of each horizontally elongated rectangle representing a circuit board. Here, the lengths of rectangles respectively indicating 10 components mounted on a circuit board, 20 components mounted on a circuit board, and 100 or more components mounted on a circuit board are shown.

The main part 82 includes header rows 821, a header column 822, and a main body part 823 in which a plurality of rectangular marks representing circuit boards (in the following description, the marks representing circuit boards will also be referred to as “circuit boards”) are arranged. A circuit board mount end time is displayed in the header column 822. The circuit board mount end time progresses from the bottom to the top, and “2020/6/1 10:40” is displayed as the mount end time of the circuit board displayed in the bottom row, and “2020/6/1 11:58” is displayed as the mount end time of the circuit board displayed in the top row. In the top row of the header rows 821, “IMPROVEMENT TARGET” 8211, “CORRESPONDING MOUNTER” 8212, and “CORRESPONDING LINE” 8213 are displayed as the names of items displayed in the respective columns. The item “IMPROVEMENT TARGET” 8211 shows the name of an improvement target device, the item “CORRESPONDING MOUNTER” 8212 shows the name of a mounter including the improvement target device, and the item “CORRESPONDING LINE” 8213 shows the name of a line including the mounter provided with the improvement target device. In the second row of the header rows 821, “NOZZLE200340”, which is the name of the improvement target device, “CM-003-1”, which is the name of the corresponding mounter, and “Line-1”, which is the name of the corresponding line, are displayed. The regions where the item name “IMPROVEMENT TARGET” and the device name are displayed in the header rows 821 are displayed in such a manner as to emphasize the improvement target device. Here, the regions are emphasized by being displayed in halftone, but it is also possible to use a background color different from the background color of other display regions. Here, the improvement target, the corresponding mounter, and the corresponding line displayed in the header rows 821 correspond to production members in the present invention. As described above, production members in the present invention are not limited to apparatuses such as the mounting apparatuses and the inspection apparatuses, but also include members constituting these apparatuses, such as a nozzle, and further include a line constituted by the mounting apparatuses and the inspection apparatuses.

As described above, as for the plurality of circuit board P1a and the like arranged in the columns 8231 to 8233 in the main part 823, the mount end time of a circuit board displayed below is earlier than the mount end time of a circuit board displayed above. That is, out of circuit boards P1a to P12a arranged in the first column 8231 corresponding to the improvement target 8211, the mount end time of the circuit board P12a is the earliest, and the mount end time of the circuit board P1a is the latest. This also applies to circuit boards P1b to P12b arranged in the second column 8232 and circuit boards P1c to P12c arranged in the third column 8233. When focusing on a specific device, apparatus, or line displayed in the header rows 821, for example, the nozzle NOZZLE200340, a time axis Ta2 (not displayed) defined for the nozzle NOZZLE200340 extends in such a manner that time progresses upward, and the plurality of circuit boards P12a to P3a, P2a, and P1a are displayed along the time axis. The circuit board P1a and like displayed in the main part 823 are displayed in a plurality of (here, 3) columns 8231 to 8233 in the lateral direction, and a plurality of circuit boards arranged in the same row represent the same circuit board. That is, circuit boards P1a, P1b, and P1c arranged in the same row represent the same circuit board. This also applies to circuit boards P2a, P2b, and P2c arranged in another row, for example. The lengths in the lateral direction of rectangles displayed in the respective columns and representing circuit boards indicate the numbers of components mounted per circuit board as shown in the legend part 81.

Bars showing quality fluctuations are displayed in such a manner as to overlap with the circuit board P1a and the like displayed in the main part 823. These bars are displayed in accordance with display manners of respective types of quality fluctuations or events as shown in the legend part 81. For example, a real fault was detected for each of the circuit boards P12a, P12b, and P12c displayed in the bottom row, and black bars Q7, Q8, and Q9 extending in the lateral direction are displayed in such a manner as to overlap with the circuit boards P12a, P12b, and P12c respectively displayed in the columns 8231, 8232, and 8233 corresponding to the improvement target nozzle, the mounter, and the line.

Event information E3 represented by a rectangle with diagonal cross hatching, which indicates issuance of an operation instruction, is displayed between the circuit board P12c displayed in the bottom row and a circuit board P11c displayed in the second row from the bottom in the column 8233 of the corresponding line 8213. This means that an operation instruction was issued between mounting performed on the circuit board P12c displayed in the bottom row and mounting performed on the circuit board P11c displayed in the second row from the bottom. The same event information is not displayed in the columns 8231 and 8232 of the improvement target 8211 and the corresponding mounter 8212, which means that the operation instruction was issued with respect to an apparatus other than the mounter CM-003-1 provided with the improvement target device NOZZLE200340 displayed in the first column, out of apparatuses included in the Line-1.

As for circuit boards P10a, P10b, and P10c displayed in the third row from the bottom, a bar Q10 hatched with lines extending diagonally up to the right, which indicates detection of a component pickup error, is displayed in such a manner as to overlap with the circuit board P10c displayed in the column 8233 of the corresponding line 8213. This means that the component pickup error occurred in a mounter other than the mounter CM-003-1 provided with the improvement target device NOZZLE200340 displayed in the first column, out of the apparatuses included in the Line-1.

As for circuit boards P8a, P8b, and P8c displayed in the fifth row from the bottom, a bar Q11 indicating detection of a real fault is displayed in such a manner as to overlap with the circuit board P8a displayed in the column 8231 of the improvement target 8211, and a bar Q12 indicating a real fault and a bar Q13 indicating the occurrence of a component pickup error are displayed in parallel to each other on the circuit board P8c displayed in the column 8233 of the corresponding line. As described above, in the case where a plurality of types of quality fluctuations are detected or occurred, bars representing the respective types of quality fluctuations are displayed. The plurality of types of quality fluctuations may also be displayed using a cumulative bar graph.

FIG. 10 shows an example in which one type of event occurred as indicated by the event information E3. In a case where a plurality of events occurred, the display region of a rectangle having the same length as a circuit board in the lateral direction is equally divided into sections for displaying the respective events.

In the main part 823 of the production condition map display screen 80 shown in FIG. 10, the plurality of circuit boards arranged in the same column are equally spaced apart from each other in the column direction, but this arrangement of the circuit boards merely indicates a temporal order, and does not indicate intervals between time points at which the circuit boards were processed. There is no limitation to this temporal expression, and the plurality of circuit boards may be arranged in the column direction at intervals corresponding to intervals between the time points at which the circuit boards were processed.

As described above, in the production condition map display screen 80, the circuit board P1a and the like, which are mounting targets, are arranged in the time axis direction with respect to each device, apparatus, and line constituting the printed circuit board mount production line, the time series of the device and the like are aligned, and aggregate results of respective types of errors are displayed in time series by being overlaid on the circuit board P1a and the like arranged in this manner. Therefore, it is possible to narrow down causes of an abnormality based on simultaneously occurring faults and errors. Also, it is possible to find time dependency such as whether or not faults and errors occurred simultaneously, successively, in a concentrated manner, or sporadically. Therefore, it is possible to determine whether it is necessary to take measures at the present time or there is no longer a need to take measures. Also, event information is arranged and displayed along the time series where the circuit board P1a and the like are arranged, and therefore, it is possible to find causes of errors and measures that were effective to improve the conditions, for example. As described above, when a plurality of types of faults and errors occurred or are detected, it is possible to analyze causes and determine measures in a short time with use of the production condition map display screen 80.

### Embodiment 3

The following describes a manager terminal 10 according to Embodiment 3 of the present invention. Except for a production condition map display screen 90 displayed in the production condition map display unit 12, the configuration of Embodiment 3 is common to Embodiments 1 and 2, and therefore, the reference numerals used in Embodiments 1 and 2 are used for the common configuration, and a detailed description thereof is omitted.

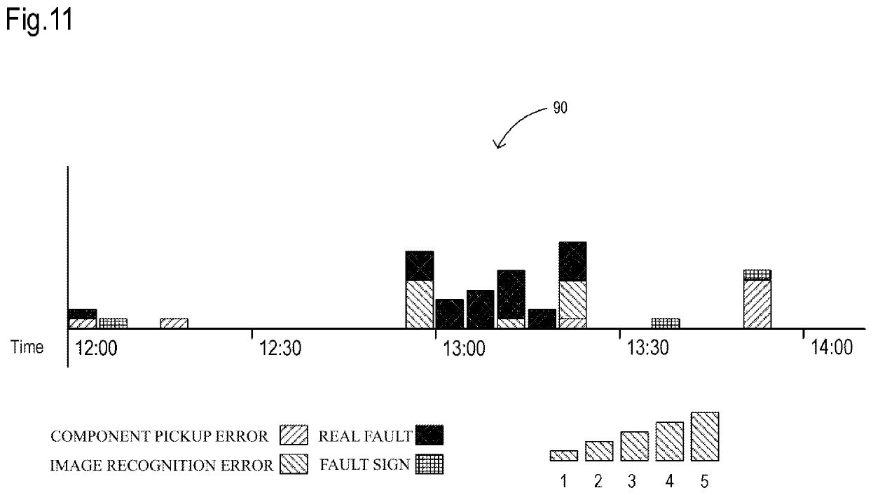

The production condition map display screen 90 shown in FIG. 11 is an example in which a cumulative bar graph is used to display faults or errors that occurred simultaneously in the printed circuit board mount production line on the same graph. In the production condition map display screen 90 according to the present embodiment, aggregate results of respective types of faults and errors occurring in or detected by the mounting apparatuses or the inspection apparatuses are displayed using different temporal expression as those adopted in the production condition map display screens 70 and 80 described in Embodiments 1 and 2. When the production condition map display screen 90 is used in combination with the production condition map display screens 70 and 80, it is possible to analyze causes and determine measures in a shorter time when a plurality of types or errors and the like occurred. The production condition map display screen 90 corresponds to chronological quality information in the present invention. It is also possible to display production condition map display screens 90 corresponding to a plurality of mounting devices or inspection devices in the vertical direction.

In FIG. 11, the horizontal axis shows the mount time point in the printed circuit board mount production line, and the vertical axis shows the number of faults or errors. In the cumulative graph, the numbers of respective types of faults and errors detected within a plot width are stacked on each other. The plot width and the scale of the mount time point are changed in accordance with a displayed time width. In FIG. 11, component pickup errors are displayed with hatching extending diagonally up to the right, image recognition errors are displayed with hatching extending diagonally up to the left, real faults are displayed in black, and fault signs are displayed with cross hatching. Here, halftone patterns are used to distinguish the different types of faults and errors, but there is no limitation to these display manners, and the different types of faults and errors are actually displayed in different colors. It is also possible to display a legend that shows correspondence between display manners of bars and types of errors and the like and correspondence between the heights of bars and the numbers of errors and the like, together with the cumulative bar graph as shown in FIG. 11. Here, the period from 12:00 to 14:00 shown by the horizontal axis corresponds to the predetermined period in the present invention, and faults and errors, which correspond to quality information, are arranged in time series.

### Embodiment 4

The following describes a manager terminal 10 according to Embodiment 4 of the present invention. Except for a production condition map display screen 91 displayed in the production condition map display unit 12, the configuration of Embodiment 4 is common to Embodiments 1 and 2, and therefore, the reference numerals used in Embodiments 1 and 2 are used for the common configuration, and a detailed description thereof is omitted.

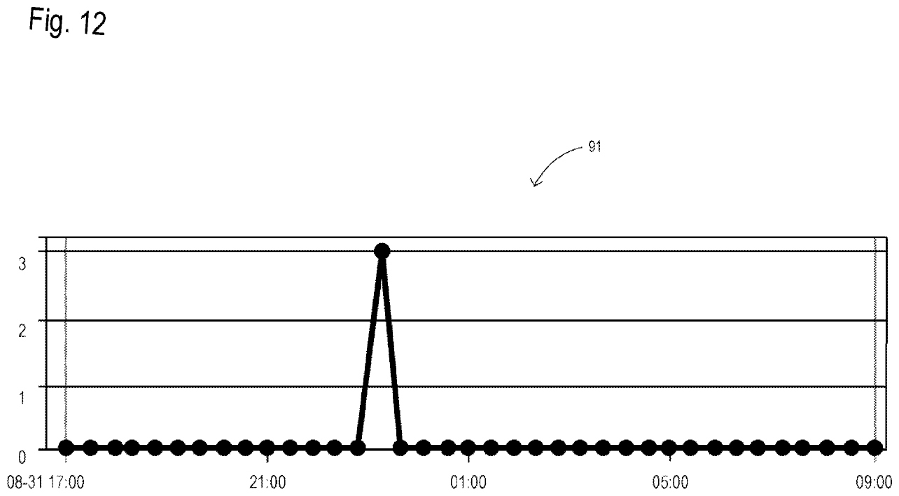

FIG. 12 shows an example in which a line graph is used to display faults or errors that occurred simultaneously in the printed circuit board mount production line on the same graph. In the production condition map display screen 91 according to the present embodiment, aggregate results of respective types of faults and errors occurring in or detected by the mounting apparatuses or the inspection apparatuses are displayed using different temporal expression as those adopted in the production condition map display screens 70 and 80 described in Embodiments 1 and 2. When the production condition map display screen 91 is used in combination with the production condition map display screens 70 and 80, it is possible to analyze causes and determine measures in a shorter time when a plurality of types or errors and the like occurred. The production condition map display screen 91 corresponds to the chronological quality information in the present invention. It is also possible to display production condition map display screens 91 corresponding to a plurality of mounting apparatuses or inspection apparatuses in the vertical direction.

In FIG. 12, the horizontal axis shows the mount time point in the printed circuit board mount production line, and the vertical axis shows the number of faults or errors. A total number of faults or errors detected within a plot width is plotted on a single plot in the line graph. The plot width and the scale of the mount time point are changed in accordance with a displayed time width. The earliest date of the plot range is displayed like “08-31” at the left end of the horizontal axis. The line graph shown in FIG. 12 shows the number of real faults within the range from 17:00 to 9:00. It is also possible to plot image recognition errors, component pickup errors, and fault signs using different display manners, such as different halftone patterns or different colors, in the line graph. Here, the period from 08-31 17:00 to 09-01 09:00 shown by the horizontal axis corresponds to the predetermined period in the present invention, and faults or errors, which correspond to quality information, are arranged in time series.

### Embodiment 5

The following describes a manager terminal 10 according to Embodiment 5 of the present invention. Except for a production condition map display screen 92 displayed in the production condition map display unit 12, the configuration of Embodiment 5 is common to Embodiments 1 and 2, and therefore, the reference numerals used in Embodiments 1 and 2 are used for the common configuration, and a detailed description thereof is omitted.

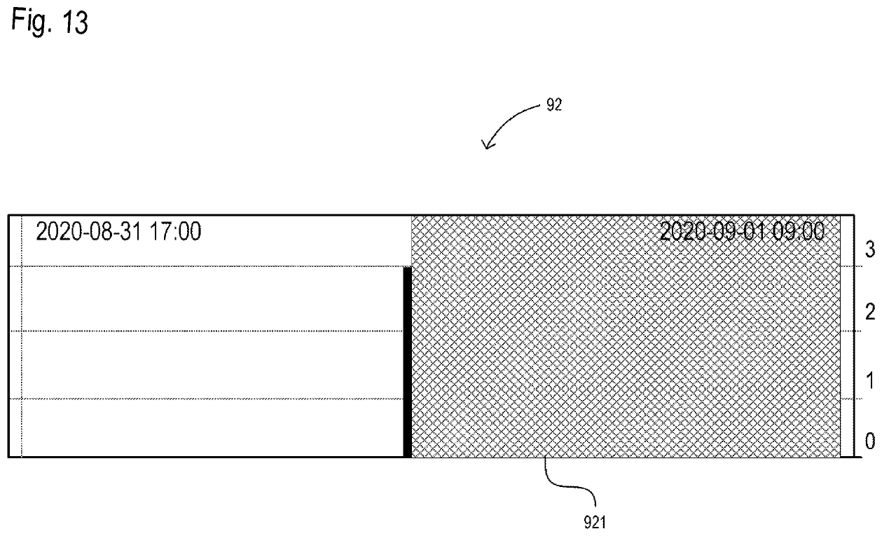

FIG. 13 shows an example in which the number of errors and the like per circuit board is plotted using a bar graph, rather than displaying a total number of errors and the like within a period in the printed circuit board mount production line. In the production condition map display screen 92 according to the present embodiment, aggregate results of respective types of faults and errors occurring in or detected by the mounting apparatuses or the inspection apparatuses are displayed using different temporal expression as those adopted in the production condition map display screens 70 and 80 described in Embodiments 1 and 2. When the production condition map display screen 92 is used in combination with the production condition map display screens 70 and 80, it is possible to analyze causes and determine measures in a shorter time when a plurality of types or errors and the like occurred. The production condition map display screen 92 corresponds to the chronological quality information in the present invention. It is also possible to display production condition map display screens 92 corresponding to a plurality of mounting apparatuses or inspection apparatuses in the vertical direction.

In FIG. 13, the horizontal axis shows the mount time point in the printed circuit board mount production line, and the vertical axis shows the number of faults or errors. In FIG. 13, real faults detected within a plot width are plotted on the bar graph. The start time “2020-08-31 17:00” and the end time “2020-09-01 09:00” of the displayed period are displayed at the upper left end and the upper right end of the graph. Time shown by the horizontal axis does not necessarily have to be uniform, and therefore, the start time and the end time of the displayed period are displayed as described above. A band-shaped background 921 with diagonal cross hatching indicates a period (an operation instruction notification period) for which a notification of an operation instruction was given. Here, the instructed operation was not performed within the displayed time range, and therefore, the background 921 is displayed to the end time. Other than the real faults shown in FIG. 13, it is also possible to show image recognition errors, component pickup errors, fault signs, etc., in different display manners, such as different halftone patterns or different colors, in the bar graph. Here, the period from 2020-08-31 17:00 to 2020-09-01 09:00 corresponds to the predetermined period in the present invention, and faults or errors, which correspond to quality information, are arranged in time series.

### Embodiment 6

The following describes a manager terminal 10 according to Embodiment 6 of the present invention. Except for a production condition map display screen 93 displayed in the production condition map display unit 12, the configuration of Embodiment 6 is common to Embodiments 1 and 2, and therefore, the reference numerals used in Embodiments 1 and 2 are used for the common configuration, and a detailed description thereof is omitted.

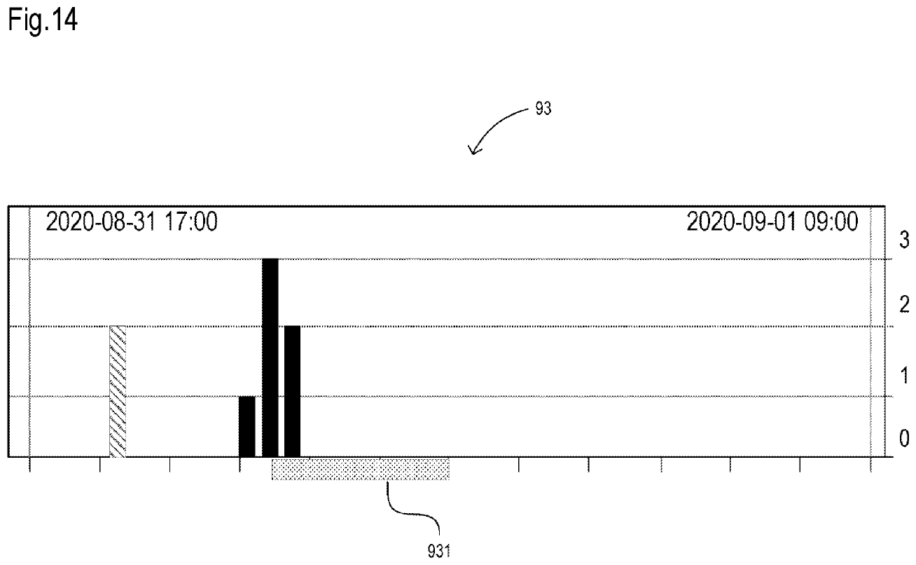

Similarly to FIG. 13, FIG. 14 shows an example in which the number of errors and the like per circuit board is plotted using a bar graph, rather than displaying a total number of errors and the like within a period in the printed circuit board mount production line. In the production condition map display screen 93 according to the present embodiment, aggregate results of respective types of faults and errors occurring in or detected by the mounting apparatuses or the inspection apparatuses are displayed using different temporal expression as those adopted in the production condition map display screens 70 and 80 described in Embodiments 1 and 2. When the production condition map display screen 93 is used in combination with the production condition map display screens 70 and 80, it is possible to analyze causes and determine measures in a shorter time when a plurality of types or errors and the like occurred. The production condition map display screen 93 corresponds to the chronological quality information in the present invention. It is also possible to display production condition map display screens 93 corresponding to a plurality of mounting apparatuses or inspection apparatuses in the vertical direction.

In FIG. 14, the horizontal axis shows the mount time point in the printed circuit board mount production line, and the vertical axis shows the number of faults or errors. In FIG. 14, image recognition errors and real faults detected within a plot width are displayed using a bar graph. Here, image recognition errors are displayed with hatching extending diagonally up to the left, and real faults are displayed in black. Also, a band-shaped dotted background 931 displayed on the scale of the time axis indicates an operation instruction notification period. Here, the background 931 is displayed only in a portion of the time axis, which means that the instructed operation was performed at the end of the range where the background 931 is displayed. The display manner of the background indicating the operation instruction notification period may be changed between the case where the instructed operation was performed and a case where the instructed operation was not performed. Other than the image recognition errors and real faults shown in FIG. 14, it is also possible to show component pickup errors, fault signs, etc., in different display manners, such as different halftone patterns or different colors, in the bar graph. The start time “2020-08-31 17:00” and the end time “2020-09-01 09:00” of the displayed period are displayed at the upper left end and the upper right end of the graph shown in FIG. 14 as well. Here, the period from 2020-08-31 17:00 to 2020-09-01 09:00 corresponds to the predetermined period in the present invention.

### Embodiment 7

The following describes a manager terminal 10 according to Embodiment 7 of the present invention. Except for a production condition map display screen 94 displayed in the production condition map display unit 12, the configuration of Embodiment 7 is common to Embodiments 1 and 2, and therefore, the reference numerals used in Embodiments 1 and 2 are used for the common configuration, and a detailed description thereof is omitted.

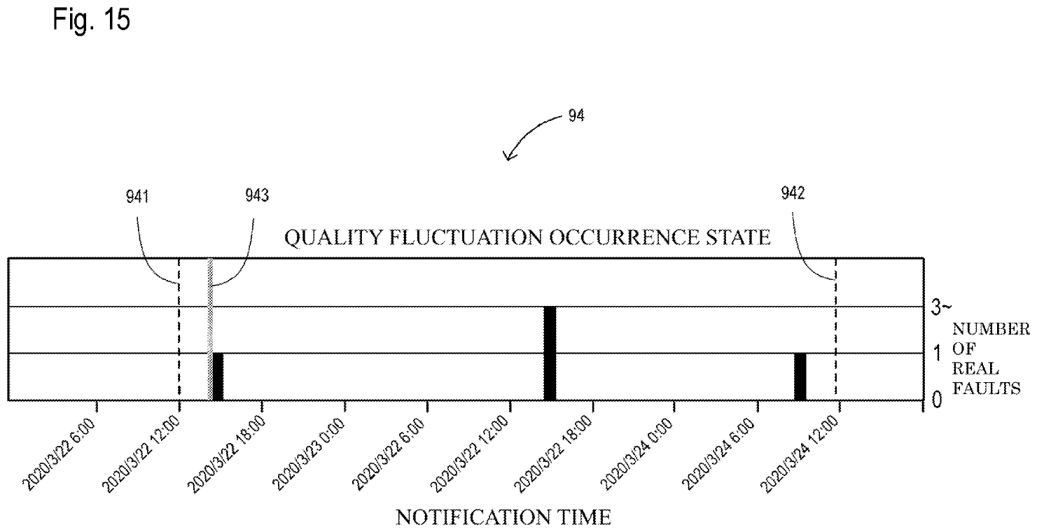

FIG. 15 shows a graph in which only frequently occurring errors are plotted. In the production condition map display screen 94 according to the present embodiment, aggregate results of respective types of faults and errors occurring in or detected by the mounting apparatuses or the inspection apparatuses are displayed using different temporal expression as those adopted in the production condition map display screens 70 and 80 described in Embodiments 1 and 2. When the production condition map display screen 94 is used in combination with the production condition map display screens 70 and 80, it is possible to analyze causes and determine measures in a shorter time when a plurality of types or errors and the like occurred. The production condition map display screen 94 corresponds to the chronological quality information in the present invention. It is also possible to display production condition map display screens 94 corresponding to a plurality of mounting apparatuses or inspection apparatuses in the vertical direction.

In FIG. 15, the horizontal axis shows time points (abnormality notification time points) at which notifications of abnormalities were issued in the printed circuit board mount production line, and the vertical axis shows the number of faults or errors. In this example, frequent occurrence of real faults was detected, and black bars showing the number of real faults are displayed on the graph. This bar graph displays only frequently occurring errors and the like out of errors and the like detected within a plot width. Broken lines 941 and 942 show boundary time points of the monitoring period. In FIG. 15, a time point at which an event such as replacement of a reel occurred is plotted as event information 943, in addition to the errors and the like. The event information 943 is represented by a grey thin rectangle that is different from the bars. Other than the real faults shown in FIG. 15, it is also possible to show image recognition errors, component pickup errors, fault signs, etc., in different display manners, such as different halftone patterns or different colors, in the bar graph. The number of errors or the like that are taken as frequently occurring errors or the like can be set to a suitable number, for example, 3 or more. Here, the period from 2020/03/22 12:00 to 2020/3/24 12:00 between the broken lines 941 and 942 corresponds to the predetermined period in the present invention, and faults or errors, which correspond to quality information, are arranged in time series.

### Embodiment 8

The following describes a manager terminal 10 according to Embodiment 8 of the present invention. Except for a production condition map display screen 95 displayed in the production condition map display unit 12, the configuration of Embodiment 8 is common to Embodiments 1 and 2, and therefore, the reference numerals used in Embodiments 1 and 2 are used for the common configuration, and a detailed description thereof is omitted.

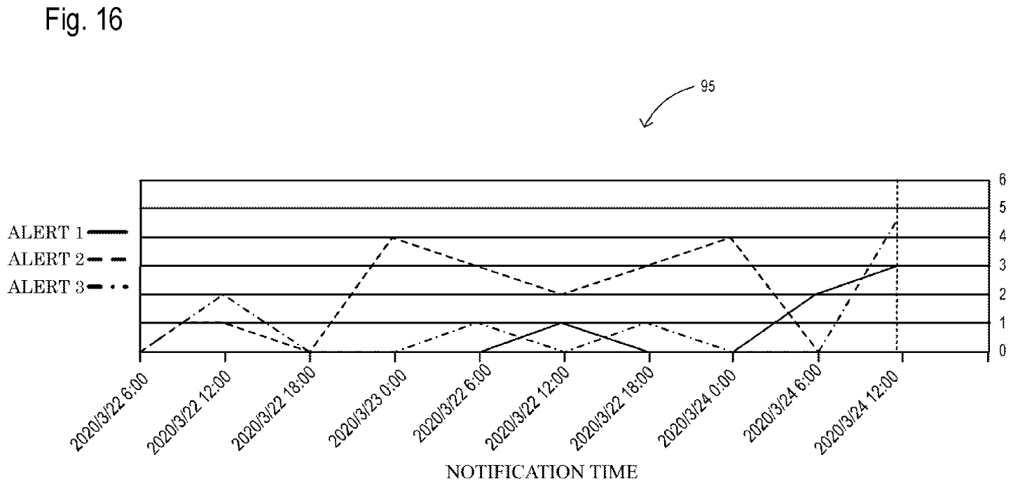

FIG. 16 shows a graph in which transition of the number of detected abnormalities, for which alerts were issued, in past aggregate results is plotted. In the production condition map display screen 95 according to the present embodiment, aggregate results of respective types of faults and errors occurring in or detected by the mounting apparatuses or the inspection apparatuses are displayed using different temporal expression as those adopted in the production condition map display screens 70 and 80 described in Embodiments 1 and 2. When the production condition map display screen 95 is used in combination with the production condition map display screens 70 and 80, it is possible to analyze causes and determine measures in a shorter time when a plurality of types or errors and the like occurred. The production condition map display screen 95 corresponds to the chronological quality information in the present invention. It is also possible to display production condition map display screens 95 corresponding to a plurality of mounting apparatuses or inspection apparatuses in the vertical direction.

In FIG. 16, the horizontal axis shows time points (abnormality notification time points) at which notifications of abnormalities were issued in the printed circuit board mount production line, and the vertical axis shows the number of faults or errors. In FIG. 16, the numbers of detected abnormalities corresponding to all alerts included in the latest notification are plotted. Here, the numbers of detected abnormalities in past notification results are plotted with respect to all alerts 1, 2, and 3 included in the latest notification, based on past alerts issued in every predetermined period through analysis. The numbers of detected abnormalities corresponding to the alerts 1, 2, and 3 are shown by a solid line, a broken line, and a dash dotted line, respectively. The dotted line extending in the vertical direction shows a boundary time point of the monitoring period. The types of errors and the like to be displayed are selected from real faults, image recognition errors, component pickup errors, fault signs, etc., as appropriate. In the case where the number of abnormalities detected for mounters is plotted, the numbers of abnormalities detected for the plurality of mounters may be plotted separately or collectively. The display time intervals are changed as appropriate by changing settings. Here, the period from 2020/03/22 6:00 to 2020/3/24 12:00 shown by the horizontal axis corresponds to the predetermined period in the present invention, and faults or errors, which correspond to quality information, are arranged in time series.

<Supplementary Note 1>

A quality improvement support apparatus (10) that supports improvement in quality of products produced by a production facility, the quality improvement support apparatus including:
a display unit (12) that displays production condition information (e.g., 80) in which quality information (e.g., Q1) regarding the quality occurring or detected in a production step performed by the production facility is arranged in time series in association with a production member or a component included in the production facility,
wherein, in the production condition information (e.g., 80), the quality information (e.g., Q1) of each unit product (e.g., B1a) constituted by one or a plurality of the products is arranged in an order in which the products (e.g., B1a) are produced.

### INDEX TO THE REFERENCE NUMERALS

10 . . . manager terminal, 12 . . . production condition map display unit, B, P . . . circuit board, Q . . . fault or error, X1 to X3, Y1 to Y4 . . . production facility

1. A quality improvement support apparatus that supports improvement in quality of products produced by a production facility, the quality improvement support apparatus comprising:
a display unit that displays production condition information in which quality information regarding the quality occurring or detected in a production step performed by the production facility is arranged in time series in association with a production member or a component included in the production facility,
wherein, in the production condition information, the quality information of each unit product constituted by one or a plurality of the products is arranged in an order in which the products are produced.

2. The quality improvement support apparatus according to claim 1,
wherein, with respect to a plurality of the production members or the components relating to the unit product, the quality information of the same unit product is arranged at the same position in the time series.

3. The quality improvement support apparatus according to claim 1,
wherein the quality information includes a plurality of types of quality information, and the respective types of quality information are displayed in different display manners.

4. The quality improvement support apparatus according to claim 1,
wherein event information indicating an event occurring or executed in relation to the production member or the component is arranged in time series together with the quality information in accordance with a temporal order between a timing of the occurrence or execution of the event and the quality information occurring or detected in relation to the production member or the component.

5. The quality improvement support apparatus according to claim 1,
wherein marks each representing the unit product are arranged in the order in a time axis direction defined for each production member or component relating to the quality information, and the quality information is displayed in association with the marks.

6. The quality improvement support apparatus according to claim 1,
wherein the production condition information includes chronological quality information regarding the quality occurring or detected in relation to the production member or the component, the chronological quality information being arranged in time series showing passage of time in a predetermined period.

7. The quality improvement support apparatus according to claim 6,
wherein a plurality of pieces of the chronological quality information corresponding to a plurality of the production members or the components are arranged vertically, the chronological quality information showing the passage of time in the predetermined period along a horizontal axis.
